(19) United States
(12) Patent Application Publication
(10) Pub. No.: US 2025/0149508 A1
(43) Pub. Date: May 8, 2025

(54) SEMICONDUCTOR DEVICES AND SEMICONDUCTOR PACKAGE INCLUDING THE SAME

(71) Applicant: Samsung Electronics Co., Ltd., Suwon-si (KR)

(72) Inventors: Jeonil Lee, Suwon-si (KR); Seryeun Yang, Suwon-si (KR); Dongkyun Lim, Suwon-si (KR)

(21) Appl. No.: 18/674,207

(22) Filed: May 24, 2024

(30) Foreign Application Priority Data
Nov. 7, 2023 (KR) 10-2023-0153006

(51) Int. Cl. H01L 25/065; H01L 23/00; H01L 23/522; H01L 23/528; H01L 23/538; H10B 12/00; H10B 80/00

(52) U.S. Cl. CPC H01L 25/0657; H01L 23/5226; H01L 23/5283; H01L 23/5381; H01L 24/08; H10B 12/50; H10B 80/00; H01L 2224/08146; H01L 2225/06541

(57) ABSTRACT

A semiconductor device includes a first chip structure that includes a memory structure and a cell routing interconnection structure that is electrically connected to the memory structure, a second chip structure that is on the first chip structure and includes a first peripheral circuit, a second peripheral circuit, a first peripheral routing interconnection structure that is electrically connected to the first peripheral circuit and the cell routing interconnection structure, and a second peripheral routing interconnection structure that is electrically connected to the second peripheral circuit, and a connection structure that extends into the first chip structure and the second chip structure, where the connection structure includes: a first connection pad, a second connection pad that overlaps the first connection pad, and an intermediate connection structure that is between the first connection pad and the second connection pad and is electrically connected to the second peripheral routing interconnection structure.

### CROSS-REFERENCE TO RELATED APPLICATION(S)

This application claims benefit of priority to Korean Patent Application No. 10-2023-0153006 filed on Nov. 7, 2023 in the Korean Intellectual Property Office, the disclosure of which is incorporated herein by reference in its entirety.

### TECHNICAL FIELD

The present disclosure relates to a semiconductor device and a semiconductor package including the same.

### BACKGROUND

As electronic devices are reduced in weight and have higher performance, miniaturization and higher performance are also desired in the semiconductor package field. In order to realize miniaturization, reduction in weight, high performance, large capacity, and high reliability of semiconductor packages, research and development on semiconductor packages with a structure in which semiconductor chips are stacked in multiple stages are being conducted.

### SUMMARY

An aspect of the present disclosure is to provide a miniaturized semiconductor device.

Another aspect of the present disclosure is to provide a miniaturized semiconductor package.

However, the purpose of the present disclosure is not limited to the above-mentioned purposes, and may be expanded in various manners without departing from the spirit and scope of the present disclosure.

According to an aspect of the present disclosure, a semiconductor device includes a first chip structure that includes a memory structure and a cell routing interconnection structure that is electrically connected to the memory structure, a second chip structure that is on the first chip structure and includes a first peripheral circuit, a second peripheral circuit, a first peripheral routing interconnection structure that is electrically connected to the first peripheral circuit and the cell routing interconnection structure, and a second peripheral routing interconnection structure that is electrically connected to the second peripheral circuit, and a connection structure that extends into the first chip structure and the second chip structure, where the connection structure includes: a first connection pad, a second connection pad overlaps the first connection pad in a first direction that is perpendicular to a lower surface of the first chip structure, and an intermediate connection structure that is between the first connection pad and the second connection pad and is electrically connected to the second peripheral routing interconnection structure.

According to an aspect of the present disclosure, a semiconductor package includes a lower substrate, and a plurality of semiconductor chips that are on the lower substrate and extend in a first direction that is perpendicular to an upper surface of the lower substrate, where a first semiconductor chip, among the plurality of semiconductor chips, includes: a first chip structure that includes a memory structure and a cell routing interconnection structure that is electrically connected to the memory structure, a second chip structure that is on the first chip structure and includes a first peripheral circuit, a second peripheral circuit, a first peripheral routing interconnection structure that is electrically connected to the first peripheral circuit and the cell routing interconnection structure, and a second peripheral routing interconnection structure that is electrically connected to the second peripheral circuit, and a connection structure that extends into the first chip structure and the second chip structure, and where the connection structure includes: a first connection pad, a second connection pad that overlaps the first connection pad in the first direction, and an intermediate connection structure that is between the first connection pad and the second connection pad and is electrically connected to the second peripheral routing interconnection structure.

According to an aspect of the present disclosure, a semiconductor device includes a first chip structure that includes a memory structure and a cell routing interconnection structure that is electrically connected to the memory structure, a second chip structure that is on the first chip structure and includes a first peripheral circuit, a second peripheral circuit, a first peripheral routing interconnection structure that is electrically connected to the first peripheral circuit and the cell routing interconnection structure, and a second peripheral routing interconnection structure that is electrically connected to the second peripheral circuit, and a connection structure that extends into the first chip structure and the second chip structure, where the second chip structure includes: a semiconductor substrate, a second insulating lower structure that overlaps the first peripheral circuit in a first direction that is perpendicular to a lower surface of the first chip structure, overlaps the second peripheral circuit in the first direction, overlaps the first peripheral routing interconnection structure in the first direction, and overlaps the second peripheral routing interconnection structure in the first direction, where the semiconductor substrate is on the second insulating lower structure, and a second insulating upper structure on the semiconductor substrate, where the connection structure includes: a first connection pad, a second connection pad that overlaps the first connection pad in the first direction, and an intermediate connection structure that is between the first connection pad and the second connection pad and is electrically connected to the second peripheral routing interconnection structure, where the intermediate connection structure includes: a first upper through-via that is electrically connected to the second connection pad and extends into the semiconductor substrate, a connecting interconnection that is electrically connected to the first connection pad, and a bridge structure that is electrically connected to the second peripheral routing interconnection structure and is between the first upper through-via and the connecting interconnection.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a view illustrating a semiconductor package according to embodiments.

FIG. 2 is a schematic cross-sectional view illustrating the embodiment of FIG. 1, taken along line I-I′.

FIG. 3 is a cross-sectional view illustrating an example of the semiconductor device of FIG. 1.

FIG. 4A is a perspective view schematically illustrating a semiconductor chip of a semiconductor device according to embodiments.

FIG. 4B is a plan view illustrating an example of portion ‘A’ in the bank of FIG. 4A.

FIG. 4C is a conceptual perspective view three-dimensionally illustrating an electrical connection relationship of semiconductor devices according to embodiments.

FIG. 5 is a cross-sectional view illustrating a cell array region and a peripheral region of a semiconductor device according to some embodiments.

FIGS. 6A and 6B are cross-sectional views illustrating a cell array region and a peripheral region of a semiconductor device according to embodiments.

FIG. 7 is a cross-sectional view illustrating a cell array region and a peripheral region of a semiconductor device according to embodiments.

FIGS. 8A and 8B are cross-sectional views illustrating a cell array region and a peripheral region of a semiconductor device according to another embodiment.

FIG. 9A is a plan view illustrating an example of the memory structure of FIGS. 8A and 8B.

FIG. 9B is a cross-sectional view schematically illustrating regions of FIG. 9A, taken along lines II-II′ and III-III′.

FIGS. 10A, 10B, 10C, 10D, and 10E are cross-sectional views illustrating an example of a method of manufacturing the semiconductor device of FIG. 5.

FIGS. 11A, 11B, 11C, and 11D are cross-sectional views illustrating an example of a method of manufacturing the semiconductor device of FIG. 6A.

FIGS. 12A, 12B, 12C, 12D, 12E, and 12F are cross-sectional views illustrating an example of a method of manufacturing the semiconductor device of FIG. 7.

FIGS. 13A, 13B, 13C, and 13D are cross-sectional views illustrating an example of a method of manufacturing the semiconductor device of FIG. 8A.

FIG. 14A is an enlarged view illustrating an example of a bonding relationship between the plurality of semiconductor chips of FIG. 3.

FIG. 14B is an enlarged view illustrating another example of a bonding relationship between the plurality of semiconductor chips of FIG. 3.

### DETAILED DESCRIPTION

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. As used herein, “an element A is on a same level as element B” refers to element A (or at least one surface thereof) being coplanar with element B (or at least one surface thereof). The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction. The term “exposed” may be used to define a relationship between particular layers or surfaces, but it does not require the layer or surface to be free of other elements or layers thereon in the completed device.

Hereinafter, embodiments will be described in more detail with reference to the attached drawings. The same reference numerals are used for the same components in the drawings, and duplicate descriptions for the same components will be omitted.

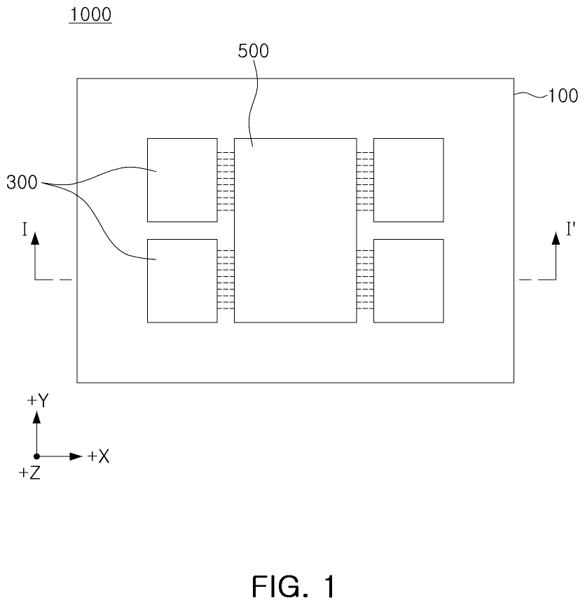

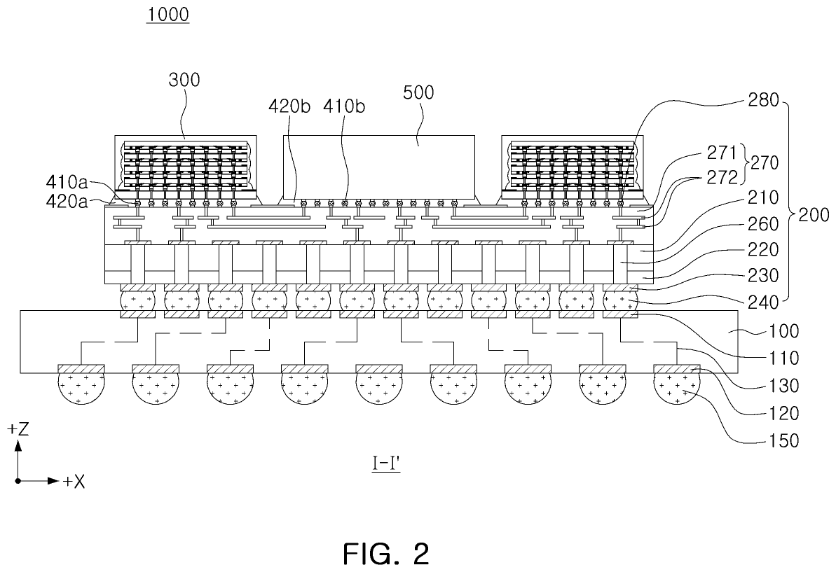

FIG. 1 is a view illustrating a semiconductor package according to embodiments. FIG. 2 is a schematic cross-sectional view illustrating the embodiment of FIG. 1, taken along line I-I′.

Referring to FIGS. 1 and 2, a semiconductor package 1000 may include a package substrate 100, an interposer 200, and at least one semiconductor device 300. In an example, the semiconductor package 1000 may further include a logic chip or processor chip 500 disposed on the interposer 200 and adjacent to the semiconductor device 300.

In some embodiments, the package substrate 100 may include an upper pad 110 disposed on an upper surface of a body, a lower pad 120 disposed on a lower surface of the body, and a redistribution circuit 130 electrically connecting the upper pad 110 and the lower pad 120. In an example, the package substrate 100 may be a support substrate on which the interposer 200, the processor chip 500, and the semiconductor device 300 are mounted, and may be a substrate for a semiconductor package including a printed circuit board (PCB), a ceramic substrate, a glass substrate, a tape interconnection substrate, or the like.

In some embodiments, the body of the package substrate 100 may include a different material depending on a type of substrate. For example, when the package substrate 100 is a printed circuit board, it may be a copper clad laminate, or a construct in which an interconnection layer is additionally laminated on one surface or both surfaces of the copper clad laminate. In an example, solder resist layers may be formed on lower and upper surfaces of the package substrate 100, respectively. The upper and lower pads 110 and 120 and the redistribution circuit 130 may form an electrical path connecting the upper and lower surfaces of the package substrate 100. The upper and lower pads 110 and 120 and the redistribution circuit 130 may include a metal material. The metal material may include, for example, at least one metal selected from copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), or carbon (C), or an alloy containing two or more metals therefrom. In an example, the redistribution circuit 130 may include redistribution layers having multiple layers, and a via connecting them. An external connection terminal 150 connected to the lower pad 120 may be disposed on the lower surface of the package substrate 100. In an example, the external connection terminal 150 may include tin (Sn), indium (In), bismuth (Bi), antimony (Sb), copper (Cu), silver (Ag), zinc (Zn), lead (Pb), and/or alloys thereof.

In some embodiments, the interposer 200 may include a substrate 210, a lower protective layer 220, a lower pad 230, a bump 240, a through-electrode 260, and an interconnection structure 270. In an example, the semiconductor device 300 and the processor chip 500 may be stacked on the package substrate 100 via the interposer 200. In an example, the interposer 200 may electrically connect the semiconductor device 300 and the processor chip 500. In an example, the substrate 210 may be formed of any one of a silicon substrate, an organic substrate, a plastic substrate, or a glass substrate. When the substrate 210 is a silicon substrate, the interposer 200 may be referred to as a silicon interposer. In the interposer 200, when the substrate 210 is an organic substrate, the interposer 200 may be referred to as a panel interposer. In an example, the lower protective layer 220 may be disposed on a lower surface of the substrate 210, and the lower pad 230 may be disposed below the lower protective layer 220. The lower pad 230 may be connected to the through-electrode 260. The semiconductor device 300 and the processor chip 500 may be electrically connected through the bump 240 disposed below the lower pad 230.

In some embodiments, the interconnection structure 270 may be disposed on an upper surface of the substrate 210, and may include an insulating layer 271 and an interconnection layer 272 having a single layer or multiple layers. When the interconnection structure 270 has a multi-layer interconnection structure, interconnection in different layers may be connected to each other through a vertical contact.

In some embodiments, the through-electrode 260 may extend from the upper surface to the lower surface of the substrate 210, and may penetrate the substrate 210. The through-electrode 260 may extend into the interconnection structure 270, and may be electrically connected to interconnections of the interconnection structure 270. In an example, when the substrate 210 is silicon, the through-electrode 260 may be referred to as a through silicon via (TSV). In an example, the interposer 200 may include only an interconnection layer therein, and may not include the through-electrode 260.

In some embodiments, the interposer 200 may be used to convert or transmit an input electrical signal between the package substrate 100 and the semiconductor device 300 or the processor chip 500. For example, the interposer 200 may not include an element such as an active element, a passive element, or the like.

In some embodiments, the bump 240 may be disposed on a lower surface of the interposer 200, and may be electrically connected to the interconnection of the interconnection structure 270. The interposer 200 may be stacked on the package substrate 100 through the bump 240. The bump 240 may be connected to the interconnection layer 272 of the interconnection structure 270 through the through-electrode 260 and the lower pad 230. In an example, portions of lower pads 230 used for power or ground may be integrated together and connected to the bump 240, such that the number of lower pads 230 may be greater than the number of bumps 240.

In some embodiments, interposer 200 may include upper pads 280 on the interconnection structure 270.

In some embodiments, the processor chip 500 may include, for example, a central processor (CPU), a graphics processor (GPU), a field programmable gate array (FPGA), a digital signal processor (DSP), a cryptographic processor, a microprocessor, a microcontroller, an analog-to-digital converter, an application-specific IC (ASIC), or the like. Depending on a type of an element included in the processor chip 500, the semiconductor package 1000 may be classified into a server semiconductor package, a mobile semiconductor package, or the like.

In some embodiments, the semiconductor package 1000 may include a first connection pattern 410a between the semiconductor device 300 and the interposer 200 and electrically connecting the semiconductor device 300 and the interposer 200, and a second connection pattern 410b between the processor chip 500 and the interposer 200 and electrically connecting the processor chip 500 and the interposer 200.

In some embodiments, the semiconductor package 1000 may include a first underfill material layer 420a filling or in a space between the semiconductor device 300 and the interposer 200 and at least partially surrounding a side surface of the first connection pattern 410a, and a second underfill material layer 420b filling or in a space between the processor chip 500 and the interposer 200 and at least partially surrounding a side surface of the second connection pattern 410b.

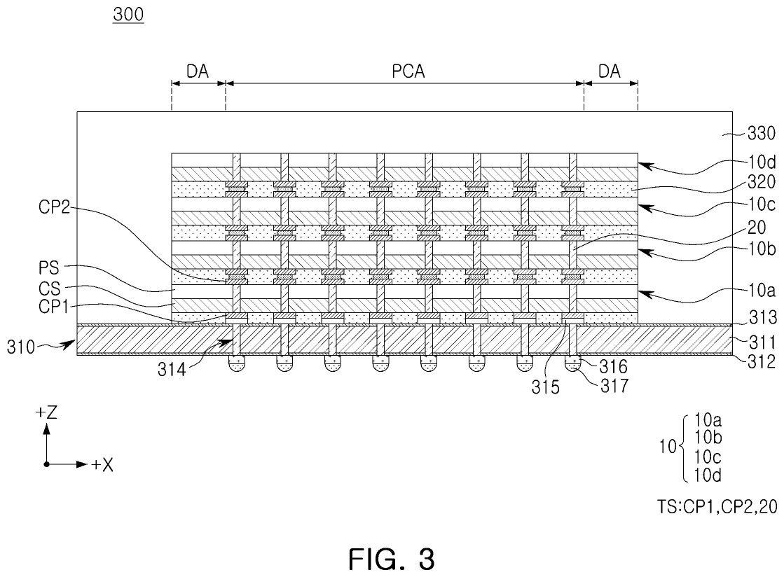

FIG. 3 is a cross-sectional view illustrating an example of the semiconductor device of FIG. 1.

Referring to FIG. 3, a semiconductor device 300 may include a base 310, a plurality of semiconductor chips 10, an adhesive material layer 320, and a mold layer 330.

In some embodiments, the base 310 may be a buffer semiconductor chip or a logic semiconductor chip. In an example, the base 310 may have a width or size greater than those of each of the plurality of semiconductor chips 10.

In some embodiments, the semiconductor device 300 may include a chip region PCA and a dummy region DA. In an example, the chip region PCA may be a region in which the plurality of semiconductor chips 10 are disposed. The dummy region DA may be a region in which a configuration for protecting a component disposed in the chip region PCA from occurrence of cracks during a sawing process separating the plurality of semiconductor chips from a semiconductor wafer is disposed.

In some embodiments, the base 310 may include a chip body 311, a lower protective layer 312 disposed on a lower surface of the chip body 311, and an upper protective layer 313 disposed on an upper surface of the chip body 311. In an example, the base 310 may further include a through-electrode structure 314 penetrating or extending into at least a portion of the chip body 311 and the upper protective layer 313, an upper pad 315 on the upper protective layer 313 and electrically connected to the through-electrode structure 314, and a lower bump 316 extending below the lower protective layer 312 and electrically connected to the through-electrode structure 314. In an example, the semiconductor device 300 may further include a lower connection pattern 317 below the base 310 and contacting the lower bump 316.

In some embodiments, the plurality of semiconductor chips 10 may be vertically stacked on the base 310.

In some embodiments, the plurality of semiconductor chips 10 may include first to fourth semiconductor chips 10a to 10d. In an example, the first to fourth semiconductor chips 10a to 10d may be sequentially stacked on the base 310 in a third direction (+Z direction).

In some embodiments, the plurality of semiconductor chips 10 are illustrated as including four semiconductor chips, but the present disclosure is not limited thereto. For example, the plurality of semiconductor chips 10 may include four or more semiconductor chips.

In some embodiments, the plurality of semiconductor chips 10 are illustrated as having the same shape, but the present disclosure is not limited thereto. For example, the plurality of semiconductor chips 10 may include semiconductor chips having different types or semiconductor chips having different shapes. In an example, the plurality of semiconductor chips 10 may be memory semiconductor chips, such as DRAM.

In some embodiments, each of the plurality of semiconductor chips 10 may include a first chip structure CS, a second chip structure PS disposed on the first chip structure CS, and a connection structure TS penetrating or extending into the first chip structure CS and the second chip structure PS.

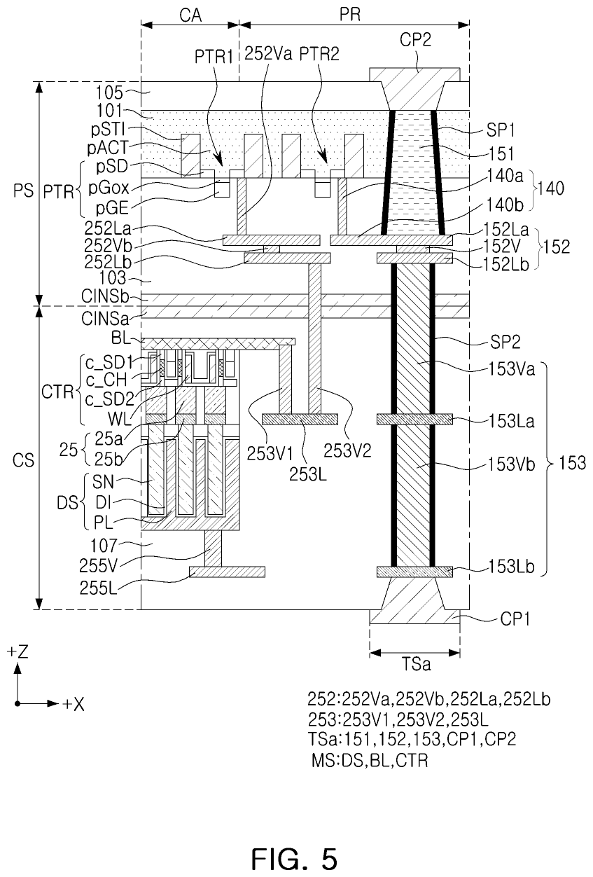

In some embodiments, the first chip structure CS may include a memory structure (e.g., a memory structure MS of FIG. 5) and a cell routing interconnection structure (e.g., a cell routing interconnection structure 253 of FIG. 5) electrically connected to the memory structure. In an example, the second chip structure PS may be stacked in a vertical direction (e.g., the third direction (+Z direction)) of the first chip structure CS. The second chip structure PS may include first and second peripheral circuits (e.g., first and second peripheral circuits PTR1 and PTR2 in FIG. 5) and a peripheral routing interconnection structure electrically connected to the first and second peripheral circuits.

In some embodiments, the connection structure TS may penetrate or extend into the first and second chip structures CS and PS in a vertical direction (e.g., the third direction (+Z direction)). In an example, the connection structure TS may include a first connection pad CP1, a second connection pad CP2 vertically overlapping the first connection pad CP1, and an intermediate connection structure 20 disposed between the first connection pad CP1 and the second connection pad CP2. In an example, the first and second connection pads CP1 and CP2 may be input/output pads. In an example, the first connection pad CP1 may be disposed adjacent to a lower surface of the first chip structure CS, and the second connection pad CP2 may be disposed adjacent to an upper surface of the second chip structure PS.

In some embodiments, the first and second connection pads CP1 and CP2 of one semiconductor chip 10, among the plurality of semiconductor chips 10, may electrically connect the one semiconductor chip and a semiconductor chip adjacent to the one semiconductor chip. In an example, a first connection pad CP1 of the first semiconductor chip 10a may electrically connect the first semiconductor chip 10a and the base 310. A second connection pad CP2 of the first semiconductor chip 10a and a first connection pad CP1 of the second semiconductor chip 10b may electrically connect the first semiconductor chip 10a and the second semiconductor chip 10b. A second connection pad CP2 of the second semiconductor chip 10b and a first connection pad CP1 of the third semiconductor chip 10c may electrically connect the second semiconductor chip 10b and the third semiconductor chip 10c. A second connection pad CP2 of the third semiconductor chip 10c and a first connection pad CP1 of the fourth semiconductor chip 10d may electrically connect the third semiconductor chip 10c and the fourth semiconductor chip 10d.

In some embodiments, the fourth semiconductor chip 10d disposed in an uppermost portion in a vertical direction, among the plurality of semiconductor chips 10, may include a connection structure TS including a first connection pad CP1 and an intermediate connection structure 20, but excluding a second connection pad CP2.

In some embodiments, the intermediate connection structure 20 disposed between the first and second connection pads CP1 and CP2 may be electrically connected to the first and second connection pads CP1 and CP2, and may be formed to have various shapes and/or structures.

In some embodiments, the adhesive material layer 320 may at least partially surround a space between the first semiconductor chip 10a and the base 310, a space between the plurality of semiconductor chips 10, and a side surface of the plurality of semiconductor chips 10. In an example, the adhesive material layer 320 may include an epoxy material. For example, the adhesive material layer 320 may be a non-conductive film (NCF), but is not limited to such a material.

In some embodiments, the mold layer 330 may be disposed to cover or overlap the plurality of semiconductor chips 10 and the adhesive material layer 320, to protect the plurality of semiconductor chips 10 and the adhesive material layer 320 from an external environment. In an example, the mold layer 330 may include an insulating material including a resin material, such as an epoxy molding compound (EMC).

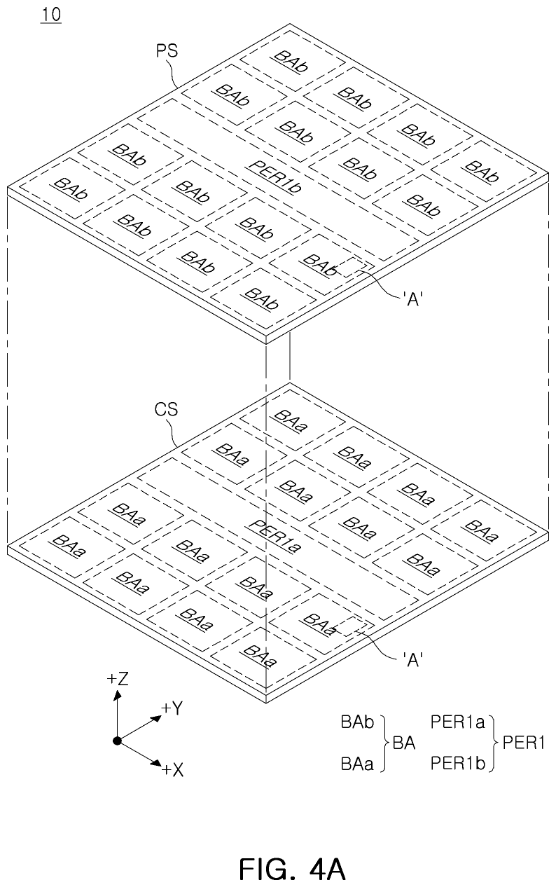

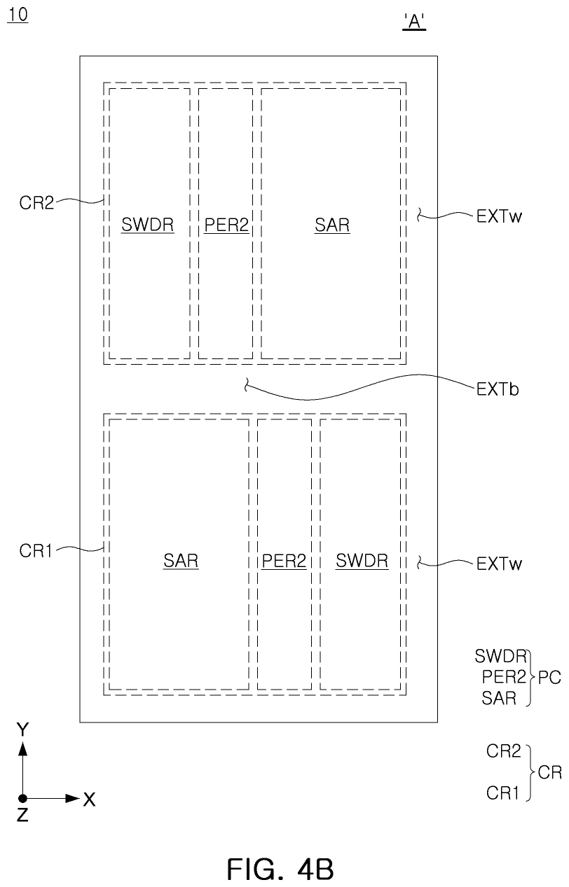

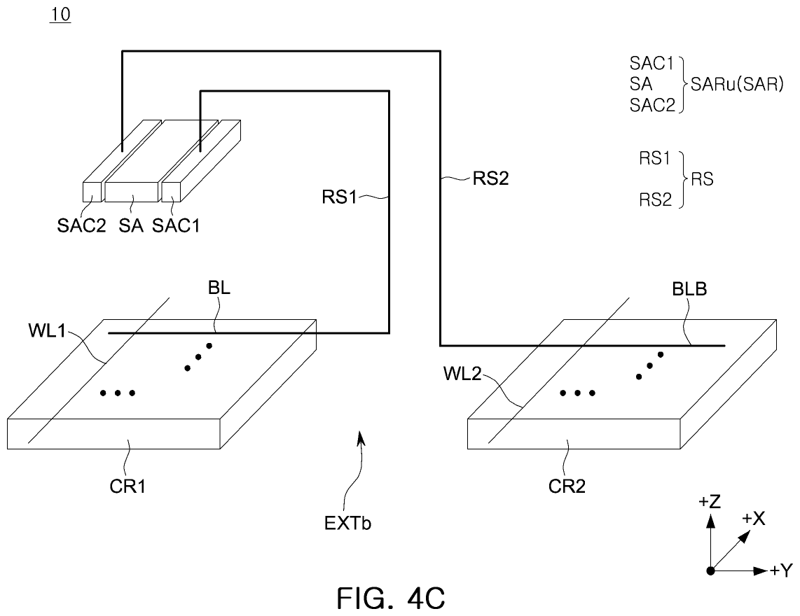

FIG. 4A is a perspective view schematically illustrating a semiconductor chip of a semiconductor device according to embodiments. FIG. 4B is a plan view illustrating an example of portion ‘A’ in the bank of FIG. 4A.

A semiconductor chip 10 illustrated in FIGS. 4A and 4B may represent one semiconductor chip among the plurality of semiconductor chips 10 illustrated in FIG. 3. Referring to FIGS. 4A and 4B, a semiconductor chip 10 may include a first chip structure CS and a second chip structure PS on the first chip structure CS. In an example, the first chip structure CS and the second chip structure PS may be sequentially stacked in a vertical direction (e.g., the third direction (+Z direction)).

In some embodiments, the semiconductor chip 10 may include a plurality of banks BA and a first peripheral region PER1. In an example, each of the plurality of banks BA may include a lower region BAa in the first chip structure CS and an upper region BAb in the second chip structure PS. In an example, the first peripheral region PER1 may include a first lower region PERla in the first chip structure CS and a first upper region PER1b in the second chip structure PS. The first peripheral region PER1 may be a peripheral circuit region in which peripheral circuits for input/output of data or commands, or input of power/ground are arranged.

In some embodiments, each of the banks BA may include memory regions CR, extension regions EXTb and EXTw adjacent to the memory regions CR, and peripheral circuit regions PC vertically overlapping the memory regions CR. In an example, the memory regions CR and the extension regions EXTb and EXTw may be disposed in lower regions BAa of the first chip structure CS, and the peripheral circuit regions PC may be disposed in upper regions BAb of the second chip structure PS.

In some embodiments, each of the memory regions CR may include cell switching elements including gate electrodes, bit lines electrically connected to the cell switching elements, and information storage structures electrically connected to the cell switching elements. The gate electrodes of the cell switching elements may be word lines.

In some embodiments, the extension regions EXTb and EXTw may include an extension region EXTb adjacent to the memory regions CR in a second direction (+Y direction), and an extension region EXTw adjacent to the memory regions CR in a first direction (+X direction). In an example, the extension region EXTb adjacent to the memory regions CR in the second direction (+Y direction) may be a bit line extension region in which the bit lines in the memory regions CR extend. The extension region EXTw adjacent to the memory regions CR in the first direction (+X direction) may be a word line extension region in which the word lines in the memory regions CR extend.

In the present disclosure, the first direction (X) and the second direction (Y) may be perpendicular to each other. The first direction (X) and the second direction (Y) may be perpendicular to the vertical direction (Z).

In some embodiments, the memory regions CR may include a first memory region CR1 and a second memory CR2 adjacent to the first memory region CR1 and spaced apart from the first memory region CR1 by the extension region EXTb.

In some embodiments, each of the peripheral circuit regions PC may include a sense amplifier region SAR, a sub-word line driver region SWDR, and a second peripheral region PER2 between the sense amplifier region SAR and the sub-word line driver region SWDR.

FIG. 4C is a conceptual perspective view three-dimensionally illustrating an electrical connection relationship of semiconductor devices according to embodiments.

Referring to FIGS. 4A to 4C, an electrical connection relationship between first and second memory regions CR1 and CR2 included in a first chip structure CS and a sense amplifier region SAR included in a second chip structure PS will be illustrated.

In some embodiments, the first memory region CR1 may include a first memory structure including a bit line BL and a word line WL1. In an example, the bit line BL may extend in the second direction (+Y), and the word line WL1 may extend in the first direction (+X).

In some embodiments, the second memory region CR2 may include a second memory structure including a bit line BLB and a word line WL2. In an example, the bit line BLB may extend in the second direction (+Y), and the word line WL2 may extend in the first direction (+X).

In some embodiments, when the first memory region CR1 is a normal memory region and the second memory region CR2 is a reference memory region, the bit line BL of the first memory region CR1 may be a bit line for sensing information stored in an information storage structure in the first memory region CR1, and the bit line BLB of the second memory region CR2 may be a complementary bit line.

Hereinafter, the bit line BL of the first memory region CR1 will be referred to as a ‘bit line,’ and the bit line BLB of the second memory region CR2 will be referred to as a complementary bit line.

In some embodiments, the sense amplifier region SAR may include a plurality of unit sense amplifier regions SARu. In an example, each of the unit sense amplifier regions SARu may include a first connection region SAC1, a second connection region SAC2, and a sense amplifier SA between the first connection region SAC1 and the second connection region SAC2.

In some embodiments, the semiconductor device 10 may include routing structures RS electrically connecting the bit line BL of the first memory region CR1, the complementary bit line BLB of the second memory region CR2, and the unit sense amplifier region SARu.

In some embodiments, the routing structures RS may include a first routing structure RS1 electrically connecting the bit line BL of the first memory region CR1 and the first connection region SAC1, and a second routing structure RS2 electrically connecting the complementary bit line BLB of the second memory region CR2 and the second connection region SAC2.

In some embodiments, the bit line BL of the first memory region CR1 may be disposed as a plurality of bit lines BL, and the bit lines BL may be spaced apart from each other in the first direction (+X direction). The complementary bit line BLB of the second memory region CR2 may be disposed as a plurality of bit lines BLB, and the complementary bit lines BLB may be spaced apart from each other in the first direction (+X direction).

In some embodiments, the bit lines BL of the first memory region CR1 may extend into an extension region EXTb, and may be electrically connected to the first routing structures RS1. The bit lines BLB of the second memory region CR2 may extend into the extension region EXTb, and may be electrically connected to the second routing structures RS2.

In some embodiments, the first memory region CR1 and the second memory region CR2 may be electrically connected to the sense amplifier region SAR. The bit lines BL of the first memory region CR1 may include n bit lines BL1, BL2, . . . , BLn, and the complementary bit lines BLB of the second memory region CR2 may include n complementary bit lines BLB1, BLB2, . . . , BLBn. The sense amplifiers SA of the sense amplifier region SAR may include n sense amplifiers SA1, SA2, . . . , SAn. One of the sense amplifiers SA1, SA2, . . . , SAn may be connected to one bit line BL1 of the bit lines BL1, BL2, . . . , BLn, and one complementary bit line BLB1 of the complementary bit lines BLB1, BLB2, . . . , BLBn.

In some embodiments, the bit lines BL and the sense amplifiers SA may be electrically connected by the first routing structure RS1, and the complementary bit lines BLB and the sense amplifiers SA may be electrically connected by the second routing structure RS2.

Next, a cross-sectional structure of the semiconductor device 10 described with reference to FIGS. 1 to 4C will be described with reference to FIGS. 5 to 8B. A region represented by “CA” in FIGS. 5 to 8B may be a memory cell array region, and may represent the first memory region CR1 of the first chip structure CS described above. A region represented by “PR” in FIGS. 5 to 8B may represent a space connected from the banks BA to the first peripheral region PER1.

FIG. 5 is a cross-sectional view illustrating a cell array region and a peripheral region of a semiconductor device according to some embodiments.

Referring to FIG. 5, a semiconductor chip (or semiconductor device) may include a first chip structure CS, a second chip structure PS vertically overlapping the first chip structure CS, and a connection structure TSa penetrating or extending into the first chip structure CS and the second chip structure PS.

In some embodiments, the semiconductor device may include a cell array region CA and a peripheral region PR. In an example, the cell array region CA may be a region overlapping a memory structure MS of the first chip structure CS. The peripheral region PR may be a region disposed side by side with or adjacent to the cell array region CA in the first direction (+X direction) and overlapping the connection structure TSa.

In some embodiments, the first chip structure CS may include a memory structure MS, a cell routing interconnection structure 253 electrically connected to the memory structure MS, a first insulating structure 107 covering or overlapping the memory structure MS and the cell routing interconnection structure 253, and a first bond insulating layer CINSa disposed on the first insulating structure 107.

In some embodiments, the memory structure MS may include bit lines BL, a cell transistor CTR, and an information storage structure DS.

In some embodiments, the bit lines BL may be electrically connected to a sense amplifier (e.g., the sense amplifier SA in FIG. 4C), as described above. In an example, the bit lines BL may be disposed on a higher level than the information storage structure DS and the cell transistor CTR (e.g., a distance between the bit line BL and a lower surface of the first chip structure CS (e.g., a lower surface of the first insulating structure 107 in which the first connection pad CP1 may be exposed) is greater than a distance between the information storage structure DS and the lower surface of the first chip structure CS and greater than a distance between the cell transistor CTR and the lower surface of the first chip structure CS).

In an example, the cell transistor CTR may include first and second cell source/drain regions c_SD1 and c_SD2, a cell vertical channel region c_CH, and word lines WL (or cell gate electrodes). In an example, the cell transistor CTR may be disposed on a higher level than the information storage structure DS (e.g., a distance between the cell transistor CTR and a lower surface of the first chip structure CS (e.g., a lower surface of the first insulating structure 107 in which the first connection pad CP1 may be exposed) is greater than a distance between the information storage structure DS and the lower surface of the first chip structure CS). The cell transistor CTR may be disposed between the bit lines BL and the information storage structure DS.

In an example, the first cell source/drain region c_SD1 may be disposed in an upper region of the cell transistor CTR. The second cell source/drain region c_SD2 may be disposed in a lower region of the cell transistor CTR. The first cell source/drain region c_SD1 may be disposed on the second cell source/drain region c_SD2, and may be disposed on a higher level than the second cell source/drain region c_SD2 (e.g., a distance between the first cell source/drain region c_SD1 and a lower surface of the first chip structure CS (e.g., a lower surface of the first insulating structure 107 in which the first connection pad CP1 may be exposed) is greater than a distance between the second cell source/drain region c_SD2 and the lower surface of the first chip structure CS). The first cell source/drain region c_SD1 may be spaced apart from the second cell source/drain region c_SD2 in a vertical direction (e.g., the third direction (+Z direction)). In an example, the cell vertical channel region c_CH may be disposed between the first cell source/drain region c_SD1 and the second cell source/drain region c_SD2.

In an example, the word lines WL (or cell gate electrodes) may face a first side surface of the cell vertical channel region c_CH. The word lines WL may be disposed on a higher level than a lower end of the second cell source/drain region c_SD2 (e.g., a distance between the word lines WL and a lower surface of the first chip structure CS (e.g., a lower surface of the first insulating structure 107 in which the first connection pad CP1 may be exposed) is greater than a distance between the lower end of the second cell source/drain region c_SD2 and the lower surface of the first chip structure CS), and may be disposed on a lower level than an upper end of the first cell source/drain region c_SD1 (e.g., a distance between the word lines WL and a lower surface of the first chip structure CS (e.g., a lower surface of the first insulating structure 107 in which the first connection pad CP1 may be exposed) is less than a distance between the upper end of the first cell source/drain region c_SD1 and the lower surface of the first chip structure CS). In an example, the word lines WL may include doped polysilicon, a metal, a conductive metal nitride, a metal-semiconductor compound, a conductive metal oxide, a conductive graphene, a carbon nanotube, or a combination thereof. For example, the word lines WL may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotube, or a combination thereof, but the present disclosure is not limited thereto. The word lines WL may include a single layer or multiple layers of the above-described materials.

In an example, the cell transistor CTR may include a cell gate dielectric layer disposed between the cell vertical channel region c_CH and the word lines WL. The cell gate dielectric layer may be in contact with the first side surface of the cell vertical channel region c_CH. In an example, the cell gate dielectric layer may include at least one of silicon oxide or a high-K dielectric. The high-K dielectric may be a dielectric having a dielectric constant higher than that of silicon oxide. The high-K dielectric may include a metal oxide or a metal oxynitride. For example, the high dielectric may be formed of HfO₂, HfSiO, HfSiON, HfTaO, HfTIO, HfZrO, ZrO₂, Al₂O₃, or a combination thereof, but the present disclosure is not limited thereto. The cell gate dielectric layer may be formed of a single layer or multiple layers of the materials described above.

In an example, the cell transistor CTR may be referred to as a cell vertical transistor, a vertical channel transistor, or a cell vertical channel transistor.

In an example, the information storage structure DS may include first electrodes SN, a second electrode PL covering or overlapping the first electrodes SN, and a dielectric layer DI between the first electrode SN and the second electrode PL. The information storage structure DS may be a memory cell capacitor capable of storing information in a memory such as DRAM or the like.

In some embodiments, the semiconductor device may include a cell contact structure 25 disposed between the cell transistor CTR and the information storage structure DS. In an example, the cell contact structure 25 may include a first cell contact layer 25a and a second cell contact layer 25b. In an example, the first cell contact layer 25a may be in contact with the cell transistor CTR, and may be electrically connected to the second cell source/drain region c_SD2. The first cell contact layer 25a may be formed as a silicon layer. In an example, the second cell contact layer 25b may be disposed below the first cell contact layer 25a. The second cell contact layer 25b may be in contact with the information storage structure DS, and may include a conductive material. The second cell contact layer 25b may be a landing pad.

In some embodiments, the cell routing interconnection structure 253 may include a first cell routing plug 253V1 electrically connected to one or more of the bit lines BL, a cell horizontal interconnection 253L electrically connected to the first cell routing plug 253V1, and a second cell routing plug 253V2 electrically connected to the cell horizontal interconnection 253L. The second cell routing plug 253V2 may be in contact with a first peripheral routing interconnection structure 252 by penetrating or extending into the first bond insulating layer CINSa and a portion of the second chip structure PS, which will be described later. In an example, the bit lines BL may be electrically connected to a first peripheral circuit PTR1, which will be described later, through the cell routing interconnection structure 253. In an example, the cell horizontal interconnection 253L may be disposed on the same level as the second cell contact layer 25b (e.g., a distance between the cell horizontal interconnection 253L and a lower surface of the first chip structure CS (e.g., a lower surface of the first insulating structure 107 in which the first connection pad CP1 may be exposed) is the same as a distance between the second cell contact layer 25b and the lower surface of the first chip structure CS).

In some embodiments, the first bond insulating layer CINSa may be disposed on the first insulating structure 107 covering or overlapping the memory structure MS and the cell routing interconnection structure 253.

In some embodiments, the first chip structure CS may further include sub-routing interconnection structures 255V and 255L that may be electrically connected to the information storage structure DS. In an example, the sub-routing interconnection structures 255V and 255L may include a vertical interconnection 255V contacting the second electrode PL, and a horizontal interconnection 255L connected to the vertical interconnection 255V.

In some embodiments, the first and second cell routing plugs 253V1 and 253V2 of the cell routing interconnection structure 253 and the vertical interconnection 255V may be contact plugs, and the cell horizontal interconnection 253L of the cell routing interconnection structure 253 and the horizontal interconnection 255L may be pads (or interconnections including pads).

In some embodiments, the second chip structure PS may include a semiconductor substrate 101, a second insulating lower structure 103 disposed below the semiconductor substrate 101, an insulating upper structure 105 disposed on the semiconductor substrate 101, and a second bond insulating layer CINSb disposed below the second insulating lower structure 103. In an example, the second chip structure PS may include a first peripheral circuit PTR1, a second peripheral circuit PTR2, a first peripheral routing interconnection structure 252 electrically connected to the first peripheral circuit PTR1, and a second peripheral routing interconnection structure 140 electrically connected to the second peripheral circuit PTR2.

In the present disclosure, the semiconductor substrate 101 may be referred to as a first substrate or a second base substrate.

In some embodiments, the second bond insulating layer CINSb may be in contact with and bonded to the first bond insulating layer CINSa. The first and second bond insulating layers CINSa and CINSb may include the same material. Each of the first bond insulating layer CINSa and the second bond insulating layer CINSb may include at least one of silicon oxide, SiCN, or SiCON.

In some embodiments, the second insulating lower structure 103, the semiconductor substrate 101, and the second insulating upper structure 105 may be sequentially formed on the second bond insulating layer CINSb in a vertical direction (e.g., +Z direction).

In some embodiments, the semiconductor substrate 101 may include an active region pACT and a device isolation region pSTI defining the active region pACT.

In some embodiments, a peripheral transistor PTR may include a gate (pGE and pGox) below the semiconductor substrate 101, and a source/drain pSD in the active region pACT on both sides of the gate (pGE and pGox). In an example, the gate (pGE and pGox) may include a gate electrode pGE and a gate dielectric layer pGox between the gate electrode pGE and the active region pACT.

In some embodiments, the peripheral transistor PTR may include a first peripheral circuit PTR1 and a second peripheral circuit PTR2. In an example, the first peripheral circuit PTR1 may vertically overlap the memory structure MS. The first peripheral circuit PTR1 may configure transistors of sense amplifiers (e.g., sense amplifiers SA in FIG. 4C). The second peripheral circuit PTR2 may overlap a region between the cell array region CA and the peripheral region PR.

In some embodiments, the first peripheral routing interconnection structure 252 may electrically connect the first peripheral circuit PTR1 and the cell routing interconnection structure 253. In an example, the first peripheral routing interconnection structure 252 may include a first vertical portion 252Va (or a fourth intermediate plug) electrically connected to the first peripheral circuit PTR1, a first horizontal portion 252La (or a third intermediate interconnection) connected to the first vertical portion 252Va, a second vertical portion 252Vb (or a third intermediate plug) disposed between the first horizontal portion 252La and the second horizontal portion 252Lb, and a second horizontal portion 252Lb (or a fourth intermediate interconnection) connected to the second vertical portion 252Vb. In an example, the second horizontal portion 252Lb of the first peripheral routing interconnection structure 252 may be in contact with the cell routing interconnection structure 253 (or the second vertical portion 253V2) of the first chip structure CS.

In some embodiments, the bit lines BL of the first chip structure CS may be electrically connected to the first peripheral circuit PTR1 through the cell routing interconnection structure 253 and the first peripheral routing interconnection structure 252 of the second chip structure PS. In an example, the second vertical interconnection 253V2 of the cell routing interconnection structure 253 may penetrate or extend into the first and second bond insulating layers CINSa and CINSb in a vertical direction to contact the second horizontal portion 252Lb of the first peripheral routing interconnection structure 252.

In some embodiments, the second peripheral circuit PTR2 may be electrically connected to the connection structure TSa through the second peripheral routing interconnection structure 140.

In some embodiments, the connection structure TSa may penetrate or extend into the first chip structure CS and the second chip structure PS in a vertical direction (e.g., +Z direction). In an example, the connection structure TSa may include a first connection pad CP1, a second connection pad CP2 vertically overlapping the first connection pad CP1, and intermediate connection structures 151, 152, and 153 (e.g., the intermediate connection structure 20 in FIG. 3) arranged between the first and second connection pads CP1 and CP2.

In some embodiments, the first and second connection pads CP1 and CP2 may be arranged to face each other with the intermediate connection structures 151, 152, and 153 therebetween. In an example, the first connection pad CP1 may be embedded in the first insulating structure 107 of the first chip structure CS, and a lower surface of the first connection pad CP1 may be exposed through the first insulating structure 107. The second connection pad CP2 may be embedded in the second insulating upper structure 105 of the second chip structure PS, and an upper surface of the second connection pad CP2 may be embedded in the second insulating upper structure 105, and may be exposed through the second insulating upper structure 105. The first and second connection pads CP1 and CP2 may vertically overlap each other. In an example, the first and second connection pads CP1 and CP2 may be input/output pads. In an example, the first and second connection pads CP1 and CP2 may include the same metal material. For example, the first and second connection pads CP1 and CP2 may include copper (Cu).

In some embodiments, the intermediate connection structures 151, 152, and 153 may include a first upper through-via 151 electrically connected to the second connection pad CP2, a connecting interconnection 153 electrically connected to the first connection pad CP1, and a bridge structure 152 disposed between the first upper through-via 151 and the connecting interconnection 153. In an example, the intermediate connection structures 151, 152, and 153 may overlap the first and second connection pads CP1 and CP2 in a vertical direction.

In some embodiments, the first upper through-via 151 may be electrically connected to the second connection pad CP2, and may penetrate or extend into a portion of the second insulating lower structure 103 and the semiconductor substrate 101. In an example, the first upper through-via 151 may include a conductive pillar (first conductive pillar) and a barrier layer (first barrier layer) covering or overlapping side and upper surfaces (+Z direction) of the conductive pillar. In an example, a side surface of the first upper through-via 151 may be covered or overlapped by a first insulating spacer SP1. In an example, the first insulating spacer SP1 may be at least partially surrounded by the semiconductor substrate 101 and a portion of the second insulating lower structure 103.

In some embodiments, the connecting interconnection 153 may be electrically connected to the first connection pad CP1, and may penetrate or extend into a portion of the first insulating structure 107 and the first and second bond insulating layers CINSa and CINSb.

In some embodiments, the connecting interconnection 153 may include first and second pads 153La and 153Lb and first and second contact plugs 153Va and 153Vb. In an example, the first pad 153La may be disposed between the first and second contact plugs 153Va and 153Vb to electrically connect the first and second contact plugs 153Va and 153Vb. The first pad 153La may be disposed on the same level as the cell horizontal interconnection 253L of the cell routing interconnection structure 253 (e.g., a distance between the cell horizontal interconnection 253L and a lower surface of the first chip structure CS (e.g., a lower surface of the first insulating structure 107 in which the first connection pad CP1 may be exposed) is the same as a distance between the first pad 153La and the lower surface of the first chip structure CS). In an example, the second pad 153Lb may be disposed between the first connection pad CP1 and the second contact plug 153Vb to electrically connect the first connection pad CP1 and the second contact plug 153Vb. The second pad 153Lb may be disposed on the same level as the horizontal interconnection 255L among the sub-routing interconnection structures 255V and 255L, but the present disclosure is not limited thereto. The second pad 153Lb and the horizontal interconnection 255L may be arranged on different levels.

In some embodiments, side surfaces of the first and second contact plugs 153Va and 153Vb may be at least partially surrounded by a second insulating spacer SP2. The first and second contact plugs 153Va and 153Vb may include a conductive pillar and a barrier layer covering or overlapping side and upper surfaces (+Z direction) of the conductive pillar.

In some embodiments, the bridge structure 152 may be disposed between the first upper through-via 151 and the connecting interconnection 153. The bridge structure 152 may include a first horizontal portion 152La electrically connected to the first upper through-via 151, a second horizontal portion 152Lb electrically connected to the connecting interconnection 153, and a vertical portion 152V (or a first intermediate plug) electrically connecting the first horizontal portion 152La and the second horizontal portion 152Lb. The first horizontal portion 152La may be electrically connected to the second peripheral routing interconnection structure 140.

In some embodiments, the second peripheral routing interconnection structure 140 may be electrically connected to the bridge structure 152. In an example, the second peripheral routing interconnection structure 140 may include a first portion 140a electrically connected to the second peripheral circuit PTR2, and a second portion 140b electrically connecting the bridge structure 152 and the first portion 140a. The intermediate connection structures 151, 152, and 153 may be electrically connected to the second peripheral circuit PTR2 through the second peripheral routing interconnection structure 140.

In some embodiments, the second peripheral routing interconnection structure 140 may be disposed on the same level as the first peripheral routing interconnection structure 252 (e.g., a distance between the second peripheral routing interconnection structure 140 and a lower surface of the second chip structure PS (e.g., a lower surface of the second insulating structure 103 that is bonded to the second bond insulating layer CINSb) is the same as a distance between the first peripheral routing interconnection structure 252 and the lower surface of the second chip structure PS). In an example, the first and second portions 140a and 140b of the second peripheral routing interconnection structure 140 may be disposed on the same level as the first vertical portion 252Va and the first horizontal portion 252La of the first peripheral routing interconnection structure 252 (e.g., a distance between each of these respective components and the lower surface of the second chip structure PS is the same).

A semiconductor device according to embodiments may include a connection structure TSa penetrating or extending into a first chip structure CS and a second chip structure PS disposed on the first chip structure CS, and an integrated a semiconductor device may be provided by being electrically connected to an adjacent semiconductor chip through the first and second connection pads CP1 and CP2 forming the connection structure TSa.

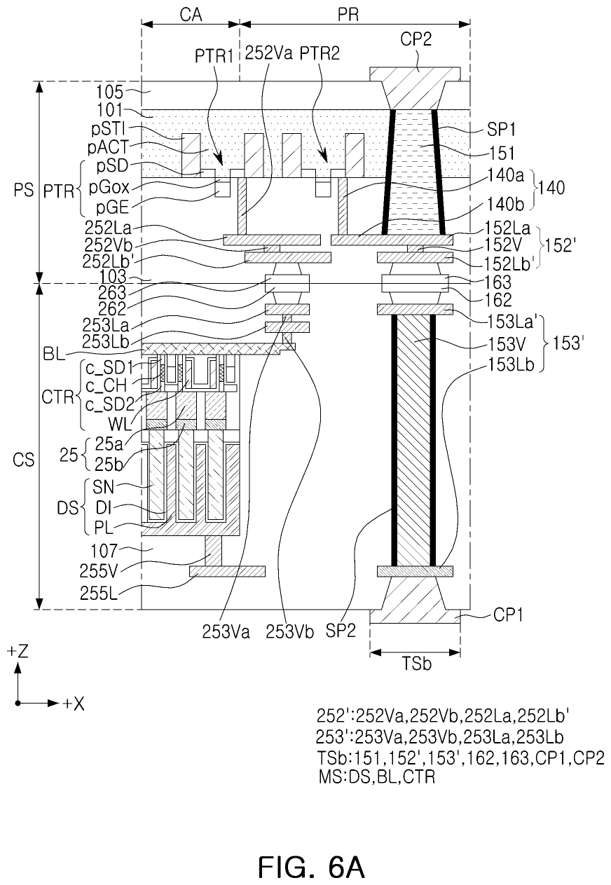

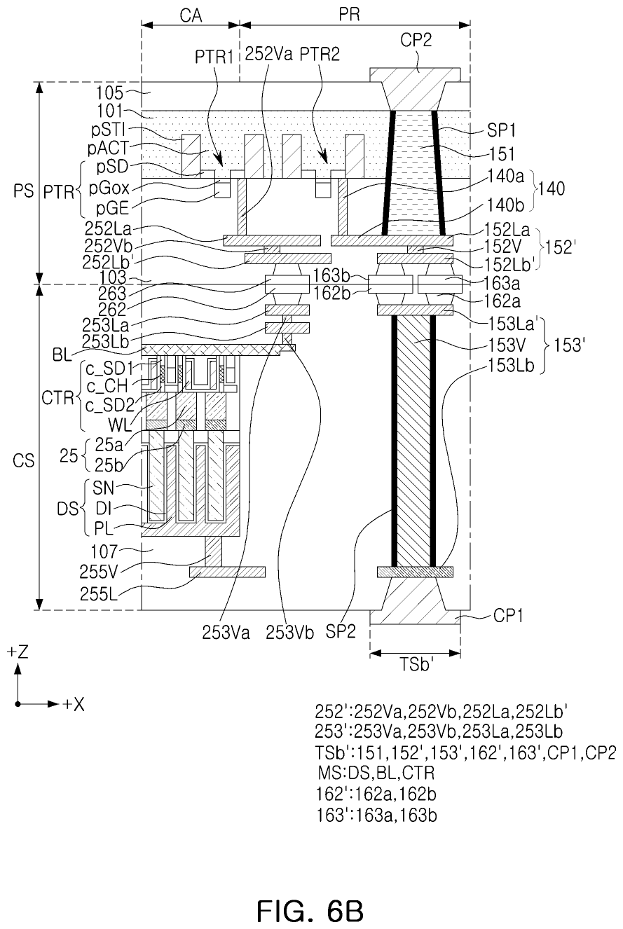

FIGS. 6A and 6B are cross-sectional views illustrating a cell array region and a peripheral region of a semiconductor device according to another embodiment.

Overlapping descriptions with regard to components identical or corresponding to those illustrated in FIG. 5, among remaining components from which a second peripheral routing interconnection structure 252′, a cell routing interconnection structure 253′, first and second bonding pads 162 and 163, first and second sub-bonding pads 262 and 263, and a connection structure TSb, which are illustrated in FIG. 6A, are excluded, will be omitted.

Referring to FIG. 6A, a semiconductor device may include a first chip structure CS, a second chip structure PS vertically overlapping the first chip structure CS, and a connection structure TSb penetrating or extending into the first chip structure CS and the second chip structure PS.

Referring to FIG. 6A, the first chip structure CS may include a memory structure MS, a cell routing interconnection structure 253′ electrically connected to the memory structure MS, a first insulating structure 107 covering or overlapping the memory structure MS and the cell routing interconnection structure 253′, and a first sub-bonding pad 262.

In some embodiments, the second chip structure PS may include a semiconductor substrate 101, a second insulating lower structure 103 disposed below the semiconductor substrate 101, a second insulating upper structure 105 disposed on the semiconductor substrate 101, and a second sub-bonding pad 263. In an example, the second chip structure PS may include a first peripheral circuit PTR1, a second peripheral circuit PTR2, a first peripheral routing interconnection structure 252′ electrically connected to the first peripheral circuit PTR1, and a second peripheral routing interconnection structure 140 electrically connected to the second peripheral circuit PTR2.

In some embodiments, the cell routing interconnection structure 253′ may be disposed on a higher level than the memory structure MS. In an example, the cell routing interconnection structure 253′ may include at least one cell routing plug (253Va and 253Vb) and at least one horizontal interconnection (253La and 253Lb). In an example, the at least one cell routing plug (253Va and 253Vb) of the cell routing interconnection structure 253′ may include a first cell routing plug 253Vb electrically connected to bit lines BL, and a second cell routing plug 253Va connecting a first cell horizontal interconnection 253La and a second cell horizontal interconnection 253Lb. The at least one horizontal interconnection (253La and 253Lb) may include a first cell horizontal interconnection 253La contacting the first sub-bonding pad 262, and a second cell horizontal interconnection 253Lb contacting the first cell routing plug 253Vb.

In some embodiments, the first sub-bonding pad 262 may be embedded in or below an upper surface of the first insulating structure 107. The second sub-bonding pad 263 may be embedded in or above a lower surface of the second insulating lower structure 103. The first sub-bonding pad 262 of the first chip structure CS may be bonded to the second sub-bonding pad 263 of the second chip structure PS. In an example, the first and second sub-bonding pads 262 and 263 may include the same material. For example, the first and second sub-bonding pads 262 and 263 may include copper (Cu).

In some embodiments, the bit lines BL may be electrically connected to the first peripheral circuit PTR1 of the second chip structure PS through the cell routing interconnection structure 253′ and the first sub-bonding pad 262.

In some embodiments, the first peripheral routing interconnection structure 252′ may electrically connect the first peripheral circuit PTR1 and the cell routing interconnection structure 253′. In an example, the first peripheral routing interconnection structure 252′ may include a first vertical portion 252Va (or a fourth intermediate plug) electrically connected to the first peripheral circuit PTR1, a first horizontal portion 252La (or a third intermediate interconnection) connected to the first vertical portion 252Va, a second vertical portion 252Vb (or a third intermediate plug) disposed between the first horizontal portion 252La and a second horizontal portion 252Lb′, and a second horizontal portion 252Lb′ (or a fourth intermediate interconnection) contacting the second sub-bonding pad 263.

In some embodiments, the bit lines BL of the first chip structure CS may be electrically connected to the first peripheral circuit PTR1 through the cell routing interconnection structure 253′, the first and second sub-bonding pads 262 and 263, and the first peripheral routing interconnection structure 252′ of the second chip structure PS. In some embodiments, the second peripheral circuit PTR2 may be electrically connected to the connection structure TSb through the second peripheral routing interconnection structure 140.

In some embodiments, the connection structure TSb may penetrate or extend into the first chip structure CS and the second chip structure PS in a vertical direction (e.g., +Z direction). In an example, the connection structure TSb may include a first connection pad CP1, a second connection pad CP2 vertically overlapping the first connection pad CP1, and an intermediate connection structure (151, 152′, 153′, 162, and 163) (e.g., the intermediate connection structure 20 in FIG. 3) arranged between the first and second connection pads CP1 and CP2. In an example, the intermediate connection structure (151, 152′ 153′, 162, and 163) may be electrically connected to the second peripheral circuit PTR2 through the second peripheral routing interconnection structure 140.

In some embodiments, the intermediate connection structure (151, 152′ 153′, 162, and 163) may include a first upper through-via 151 electrically connected to the second connection pad CP2, a connecting interconnection 153′ electrically connected to the first connection pad CP1, a bridge structure 152′ disposed between the first upper through-via 151 and the connecting interconnection 153′, and first and second bonding pads 162 and 163. In an example, the intermediate connection structure (151, 152′ 153′, 162, and 163) may overlap the first and second connection pads CP1 and CP2 in a vertical direction (+Z direction).

In some embodiments, the first bonding pad 162 may be embedded in or below the upper surface of the first insulating structure 107. The second bonding pad 163 may be embedded in or above the lower surface of the second insulating lower structure 103. In an example, the first bonding pad 162 may be bonded to the second bonding pad 163. In an example, the first and second bonding pads 162 and 163 may be disposed on the same level as the first and second sub-bonding pads 262 and 263.

In some embodiments, a width of each of the first and second bonding pads 162 and 163 in the first direction (+X direction) may be greater than a width of each of the first and second sub-bonding pads 262 and 263 in the first direction (+X direction). However, the present disclosure is not limited thereto, and the width of each of the first and second bonding pads 162 and 163 in the first direction (+X direction) may be equal to the width of each of the first and second sub-bonding pads 262 and 263 in the first direction (+X direction). In this regard, description will be made with reference to FIG. 6B.

In some embodiments, the first upper through-via 151 may be electrically connected to the second connection pad CP2, and may penetrate or extend into a portion of the second insulating lower structure 103 and the semiconductor substrate 101.

In some embodiments, the connecting interconnection 153′ may be disposed between the first connection pad CP1 and the first bonding pad 162, and may penetrate or extend into a portion of the first insulating structure 107. In an example, the connecting interconnection 153′ may include first and second pads 153La′ and 153Lb, and a contact plug 153V disposed between the first pad 153La′ and the second pad 153Lb. In an example, the first pad 153La′ may be in contact with the first bonding pad 162, and the second pad 153Lb may be in contact with the first connection pad CP1.

In some embodiments, the bridge structure 152′ may include a first horizontal portion 152La electrically connected to the first upper through-via 151, and a second horizontal portion 152Lb′ electrically connected to the second bonding pad 163, and a vertical portion 152V disposed between the first and second horizontal portions 152La and 152Lb′.

In some embodiments, the bridge structure 152′ may be disposed on the same level as the first peripheral routing interconnection structure 252′. In an example, the first and second horizontal portions 152La and 152Lb′ may be disposed on the same level as the first and second horizontal portions 252La and 252Lb′. The vertical portion 152V may be disposed on the same level as the second vertical portion 252Vb.

Referring to FIG. 6B, overlapping descriptions with regard to components identical or corresponding to those illustrated in FIG. 6A, among remaining components from which a first bonding pad 162′ and a second bonding pad 163′ are excluded, will be omitted.

Referring to FIG. 6B, a semiconductor device according to some embodiments may include a connection structure TSb′ including an intermediate connection structure (151, 152′, 153′, 162′, and 163′).

According to some embodiments, the intermediate connection structure (151, 152′, 153′, 162′, and 163′) may include a first upper through-via 151 electrically connected to a second connection pad CP2 and penetrating or extending into a semiconductor substrate 101, a connecting interconnection 153′ electrically connected to a first connection pad CP1, a bridge structure 152′, and first and second bonding pads 162′ and 163′. In an example, the first bonding pads 162′ may include at least two bonding pads 162a and 162b, and the second bonding pads 163′ may include at least two bonding pads 163a and 163b.

In some embodiments, each of the first bonding pads 162′ may have the same size as a first sub-bonding pad 262. Each of the second bonding pads 163′ may have the same size as a second sub-bonding pad 263. In an example, the first and second bonding pads 162′ and 163′ may have the same size as the first and second sub-bonding pads 262 and 263, respectively. In an example, in a process of manufacturing the semiconductor device, the first and second bonding pads 162′ and 163′ may be formed in the same process as the first and second sub-bonding pads 262 and 263, and thus a process efficiency of the semiconductor device may increase.

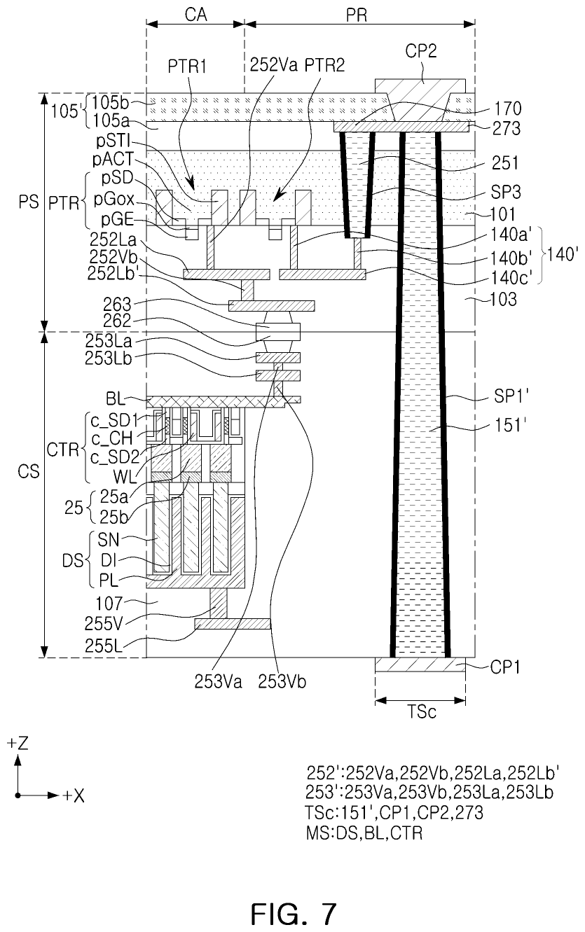

FIG. 7 is a cross-sectional view illustrating a cell array region and a peripheral region of a semiconductor device according to another embodiment.

Overlapping descriptions with regard to components identical or corresponding to those illustrated in FIGS. 5 and 6A, among remaining components from which a second peripheral routing interconnection structure (140′, 170, and 251) and a connection structure TSc, illustrated in FIG. 7, are excluded, will be omitted.

Referring to FIG. 7, a semiconductor device may include a first chip structure CS, a second chip structure PS vertically overlapping the first chip structure CS, and a connection structure TSc penetrating or extending into the first chip structure CS and the second chip structure PS.

In some embodiments, the first chip structure CS may include a memory structure MS, a cell routing interconnection structure 253′ electrically connected to the memory structure MS, a first insulating structure 107 covering or overlapping the memory structure MS and the cell routing interconnection structure 253′, and a first sub-bonding pad 262.

In some embodiments, the second chip structure PS may include a semiconductor substrate 101, a second insulating lower structure 103 disposed below the semiconductor substrate 101, a second insulating upper structure 105′ disposed on the semiconductor substrate 101, and a second sub-bonding pad 263 embedded in the second insulating lower structure 103. In an example, the second chip structure PS may include a first peripheral circuit PTR1, a second peripheral circuit PTR2, a first peripheral routing interconnection structure 252′ electrically connected to the first peripheral circuit PTR1, and a second peripheral routing interconnection structure (140′, 170, and 251) electrically connected to the second peripheral circuit PTR2.

In some embodiments, the second insulating lower structure 103, the semiconductor substrate 101, and the second insulating upper structure 105′ may be sequentially stacked in a vertical direction (e.g., +Z direction). In an example, the second insulating upper structure 105′ may include a 2-1 insulating upper structure 105a and a 2-2 insulating upper structure 105b, disposed on the semiconductor substrate 101. In an example, an upper surface of a second connection pad CP2 may be exposed through the 2-2 insulating upper structure 105b.

In some embodiments, the second peripheral circuit PTR2 may be electrically connected to the connection structure TSc through the second peripheral routing interconnection structure (140′, 251, and 170).

In some embodiments, the connection structure TSc may penetrate or extend into the first chip structure CS and the second chip structure PS in a vertical direction (e.g., +Z direction). In an example, the connection structure TSc may include a first connection pad CP1, a second connection pad CP2 vertically overlapping the first connection pad CP1, and an intermediate connection structures (151′ and 273) (e.g., the intermediate connection structure 20 in FIG. 3) disposed between the first and second connection pads CP1 and CP2. In an example, the intermediate connection structure (151′ and 273) may be electrically connected to the second peripheral circuit PTR2 through the second peripheral routing interconnection structure (140′, 170, and 251).

In some embodiments, the intermediate connection structure (151′ and 273) may include a first upper through-via 151′ electrically connected to the first connection pad CP1 and penetrating or extending into the semiconductor substrate 101, and a bridge pad 273 disposed between the first upper through-via 151′ and the first connection pad CP1.

In some embodiments, the first upper through-via 151′ may be electrically connected to the first connection pad CP1 through the bridge pad 273. The first upper through-via 151′ may penetrate or extend into the first insulating structure 107 of the first chip structure CS, the second insulating lower structure 103 of the second chip structure PS, and the semiconductor substrate 101 in a vertical direction. In an example, the first upper through-via 151′ may include a conductive pillar and a barrier layer covering or overlapping side and upper surfaces (+Z direction) of the conductive pillar. In an example, a side surface of the first upper through-via 151′ may be covered or overlapped by a first insulating spacer SP1′.

In some embodiments, the bridge pad 273 may be embedded in the 2-1 insulating upper structure 105a, and may cover or overlap the 2-2 insulating upper structure 105b. The bridge pad 273 may be physically and/or electrically connected to the horizontal pad 170 of the second peripheral routing interconnection structure (140′, 170, and 251).

In some embodiments, the second peripheral routing interconnection structure (140′, 170, and 251) may include an interconnection structure 140′ electrically connected to the second peripheral circuit PTR2, a second through-via 251 electrically connected to the interconnection structure 140′ and penetrating or extending into the semiconductor substrate 101, and a horizontal pad 170 electrically connecting the first upper through-via 151′ and the second through-via 251.

In some embodiments, the second through-via 251 may be disposed to be spaced apart from the first upper through-via 151′ in the first direction (e.g., +X direction). In an example, the second through-via 251 may include a conductive pillar (third conductive pillar) and a barrier layer (third barrier layer) covering or overlapping side and lower surfaces (−Z direction) of the conductive pillar. A side surface of the second through-via 251 may be covered or overlapped by a third insulating spacer SP3.

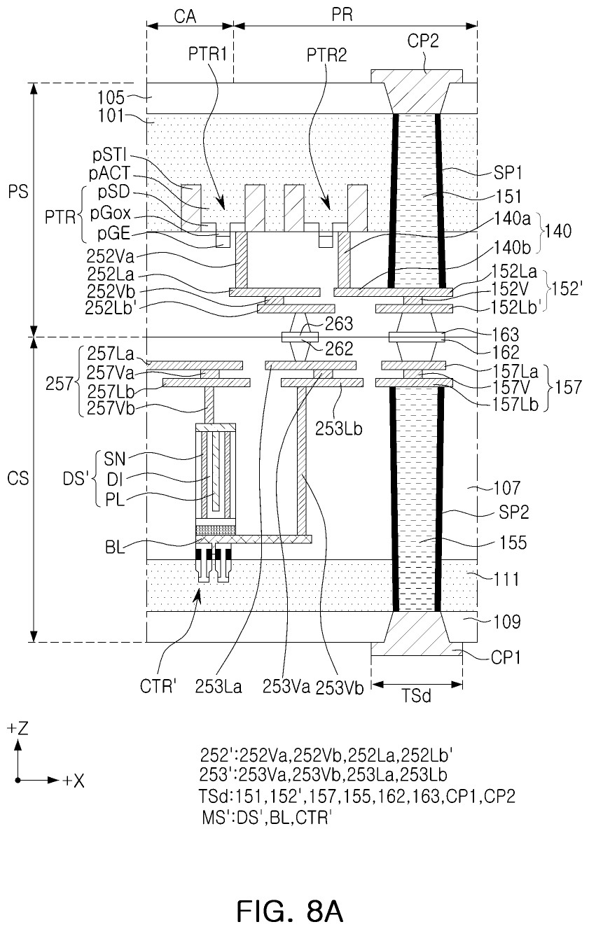

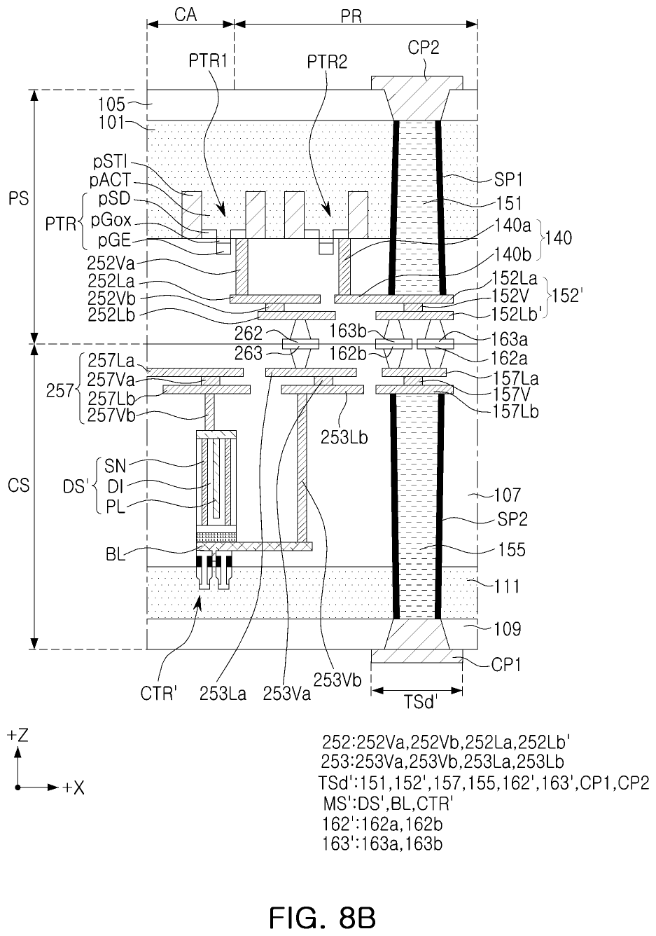

In some embodiments, the interconnection structure 140′ may include a first vertical portion 140a′ electrically connected to the second peripheral circuit PTR2, a second vertical portion 140b′ electrically connected to the second through-via 251, and a horizontal portion 140c′ connecting the first and second vertical portions 140a′ and 140b′. In an example, the horizontal portion 140c′ of the interconnection structure 140′ may be disposed on the same level as the first horizontal portion 252La of the first peripheral routing interconnection structure 252′, but the present disclosure is not limited thereto. FIGS. 8A and 8B are cross-sectional views illustrating a cell array region and a peripheral region of a semiconductor device according to some embodiments.

Referring to FIG. 8A, a semiconductor chip (or semiconductor device) may include a first chip structure CS, a second chip structure PS vertically overlapping the first chip structure CS, and a connection structure TSd penetrating or extending into the first chip structure CS and the second chip structure PS.

In some embodiments, the semiconductor device may include a cell array region CA and a peripheral region PR. In an example, the cell array region CA may be a region overlapping a memory structure MS' of the first chip structure CS. The peripheral region PR may be a region spaced apart from the cell array region CA in the first direction (+X direction) and overlapping the connection structure TSd.

In some embodiments, the first chip structure CS may include a semiconductor substrate 111, a first insulating lower structure 109 disposed below the semiconductor substrate 111, and a first insulating upper structure 107 disposed on the semiconductor substrate 111. In an example, the first chip structure CS may include a memory structure MS' and a cell routing interconnection structure 253′ electrically connected to the memory structure MS′.

In this document, the semiconductor substrate 111 may be referred to as a second substrate or a third base substrate.

In an example, the first chip structure CS may further include a sub-routing interconnection structure 257 electrically connected to an information storage structure DS′. In an example, the sub-routing interconnection structure 257 may include at least one vertical interconnection (257Va and 257Vb) and at least one horizontal interconnection (257La and 257Lb). In an example, the sub-routing interconnection structure 257 may include the vertical interconnection 257Vb electrically connected to a second electrode PL of the information storage structure DS′.

In some embodiments, the second chip structure PS may include a semiconductor substrate 101, a second insulating lower structure 103 disposed below the semiconductor substrate 101, an insulating upper structure 105 disposed on the semiconductor substrate 101, and a second sub-bonding pad 263 embedded in the second insulating lower structure 103. In an example, the second chip structure PS may include a first peripheral circuit PTR1, a second peripheral circuit PTR2, a first peripheral routing interconnection structure 252′ electrically connected to the first peripheral circuit PTR1, and a second peripheral routing interconnection structure 140 electrically connected to the second peripheral circuit PTR2.

In some embodiments, the memory structure MS' may include bit lines BL, a cell transistor CTR′, and an information storage structure DS′.

In some embodiments, the bit lines BL may be disposed between the cell transistor CTR′ and the information storage structure DS′.

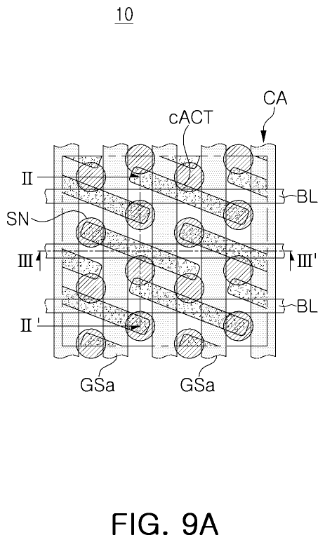

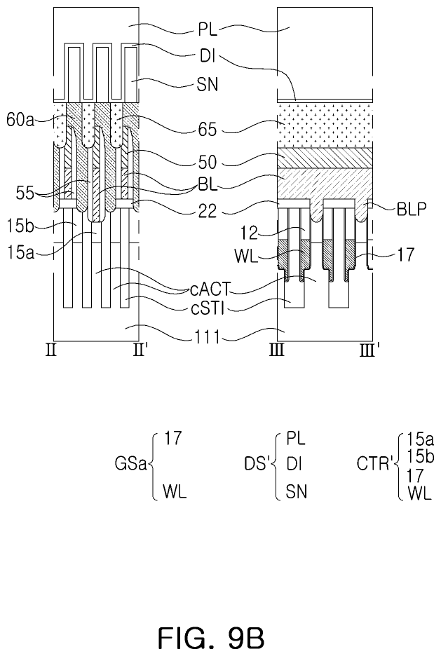

The cell transistor CTR′ and information storage structure DS' of FIG. 8A will be described with reference to FIGS. 9A and 9B described later.

In some embodiments, a first sub-bonding pad 262 may be embedded in or below an upper surface of the first insulating upper structure 107. A second sub-bonding pad 263 may be embedded in or above a lower surface of the second insulating lower structure 103. The first sub-bonding pad 262 of the first chip structure CS may be bonded to the second sub-bonding pad 263 of the second chip structure PS. In an example, the first and second sub-bonding pads 262 and 263 may include the same material. For example, the first and second sub-bonding pads 262 and 263 may include copper (Cu).

In some embodiments, the connection structure TSd may penetrate or extend into the first chip structure CS and the second chip structure PS in a vertical direction (e.g., +Z direction). In an example, the connection structure TSd may include a first connection pad CP1, a second connection pad CP2 vertically overlapping the first connection pad CP1, and an intermediate connection structure (151, 152′, 155, 157, 162, and 163) (e.g., the intermediate connection structure 20 in FIG. 3) disposed between the first and second connection pads CP1 and CP2. In an example, the intermediate connection structure (151, 152′, 155, 157, 162, and 163) may be electrically connected to the second peripheral circuit PTR2 through the second peripheral routing interconnection structure 140.

In some embodiments, the second peripheral routing interconnection structure 140 may include a first portion 140a electrically connected to the second peripheral circuit PTR2, and a second portion 140b electrically connecting the first portion 140a and the bridge structure 152. In an example, the intermediate connection structure (151, 152′, 155, 157, 162, and 163) may be electrically connected to the second peripheral circuit PTR2 through the second peripheral routing interconnection structure 140.

In some embodiments, the intermediate connection structure (151, 152′, 155, 157, 162, and 163) may include a first upper through-via 151 electrically connected to the second connection pad CP2 and penetrating or extending into the semiconductor substrate 101, a first lower through-via 155 electrically connected to the first connection pad CP1 and penetrating or extending into the semiconductor substrate 111, a bridge structure 152′, first and second bonding pads 162 and 163, and an auxiliary interconnection structure 157 disposed between the first bonding pad 162 and the first lower through-via 155. In an example, the intermediate connection structure (151, 152′, 155, 157, 162, and 163) may overlap the first and second connection pads CP1 and CP2.

In some embodiments, the first upper through-via 151 may be electrically connected to the second connection pad CP2, and may penetrate or extend into a portion of the second insulating lower structure 103 and the semiconductor substrate 101.

In some embodiments, the first lower through-via 155 may be electrically connected to the first connection pad CP1, and may penetrate or extend into a portion of the first insulating upper structure 107 and the semiconductor substrate 111. The first lower through-via 155 may include a conductive pillar (second conductive pillar) and a barrier layer (second barrier layer) covering or overlapping side and lower surfaces (−Z direction) of the conductive pillar.

In some embodiments, the bridge structure 152′ may include a first horizontal portion 152La electrically connected to the first upper through-via 151, and a second horizontal portion 152Lb′ electrically connected to the second bonding pad 163, and a vertical portion 152V disposed between the first and second horizontal portions 152La and 152Lb′.

In some embodiments, the first bonding pad 162 may be embedded in or below the upper surface of the first insulating upper structure 107. The second bonding pad 163 may be embedded in or above the lower surface of the second insulating lower structure 103. In an example, the first bonding pad 162 may be bonded to the second bonding pad 163. In an example, the first and second bonding pads 162 and 163 may be disposed on the same level as the first and second sub-bonding pads 262 and 263.

In some embodiments, a width of each of the first and second bonding pads 162 and 163 in the first direction (+X direction) may be greater than a width of each of the first and second sub-bonding pads 262 and 263 in the first direction (+X direction). However, the present disclosure is not limited thereto, and the width of each of the first and second bonding pads 162 and 163 in the first direction (+X direction) may be equal to the width of each of the first and second sub-bonding pads 262 and 263 in the first direction (+X direction). In this regard, description will be made with reference to FIG. 8B.

In some embodiments, the auxiliary interconnection structure 157 may be disposed between the first lower through-via 155 and the first bonding pad 162. In an example, the auxiliary interconnection structure 157 may include a first auxiliary horizontal interconnection 157La contacting the first bonding pad 162, a second auxiliary horizontal interconnection 157Lb contacting the first lower through-via 155, and an auxiliary plug 157V electrically connecting the first auxiliary horizontal interconnection 157La and the second auxiliary horizontal interconnection 157Lb.

Referring to FIG. 8B, overlapping descriptions with regard to components identical or corresponding to those illustrated in FIG. 8A, among remaining components from which a first bonding pad 162′ and a second bonding pad 163′ are excluded, will be omitted.

Referring to FIG. 8B, a semiconductor device according to some embodiments may include a connection structure TSd′ including an intermediate connection structure (151, 152′, 155, 157, 162′, and 163′).

Referring to FIG. 8B, the intermediate connection structure (151, 152′, 155, 157, 162′, and 163′) may include a first upper through-via 151 electrically connected to a second connection pad CP2 and penetrating or extending into a semiconductor substrate 101, a first lower through-via 155 electrically connected to a first connection pad CP1 and penetrating or extending into the semiconductor substrate 111, a bridge structure 152′, and first and second bonding pads 162′ and 163′. In an example, the first bonding pads 162′ may include at least two bonding pads 162a and 162b, and the second bonding pads 163′ may include at least two bonding pads 163a and 163b.

With reference to FIGS. 9A and 9B, an example of a first chip structure CS including a memory structure (MS' in FIG. 8A) described above will be described.

FIG. 9A is a plan view illustrating an example of the memory structure of FIGS. 8A and 8B. FIG. 9B is a cross-sectional view schematically illustrating regions of FIG. 9A, taken along lines II-II′ and III-III′.

Referring to FIGS. 9A and 9B, a lower base of a first chip structure CS may include a semiconductor substrate 111, cell active regions cACT on the semiconductor substrate 111, and a cell device isolation region cSTI disposed on the semiconductor substrate 111 and disposed on a side surface of the cell active regions cACT. The cell active regions cACT may have a shape protruding or extending in a vertical direction from the semiconductor substrate 111. The cell device isolation region cSTI may be formed by shallow trench isolation. The cell device isolation region cSTI may be formed of an insulating material such as silicon oxide and/or silicon nitride, or the like.

The first chip structure CS may include cell gate structures GSa embedded in the cell active regions cACT and extending into the cell device isolation region cSTI, and cell gate capping layers 12 on the cell gate structures GSa. The cell gate capping layers 12 may be formed of an insulating material.

The cell gate structures GSa and the cell gate capping layers 12 may be disposed in cell gate trenches crossing or intersecting the cell active region cACT and extending into the cell device isolation region cSTI.

Each of the cell gate structures GSa may include a cell gate dielectric layer 17 and word lines WL on the cell gate dielectric layer 17. The word lines WL may be cell gate electrodes.

The first chip structure CS may further include first source/drain regions 15a and second source/drain regions 15b arranged in the cell active regions cACT. The cell gate structures GSa and the first and second source/drain regions 15a and 15b may form cell transistors CTR′. The cell transistors CTR′ may be cell switching devices.

The first chip structure CS may include a buffer insulating layer 22 on the cell active regions cACT and the cell device isolation region cSTI, bit lines BL on the buffer insulating layer 22 and including plug portions BLP penetrating or extending into the buffer insulating layer 22, bit line capping layers 50 on the bit lines BL, cell contact structures 60a disposed on both sides of the bit lines BL and including pad portions extending onto the bit line capping layers 50, an insulating separation structure 65 disposed between the pad portions of the cell contact structures 60a and extending in a downward direction, and insulating spacers 55 on side surfaces of the bit lines BL and the bit line capping layers 50.

The plug portions BLP of the bit lines BL may be electrically connected to the first source/drain regions 15a. The cell contact structures 60a may be electrically connected to the second source/drain regions 15b.

An information storage structure DS′, as described in FIG. 8A, may be disposed on the cell contact structures 60a and the insulating separation structure 65. In the information storage structure DS′, first electrodes SN may be electrically connected to the cell contact structures 60a, a dielectric layer DI may cover or overlap the first electrodes SN, and a second electrode PL may be disposed on the dielectric layer DI.

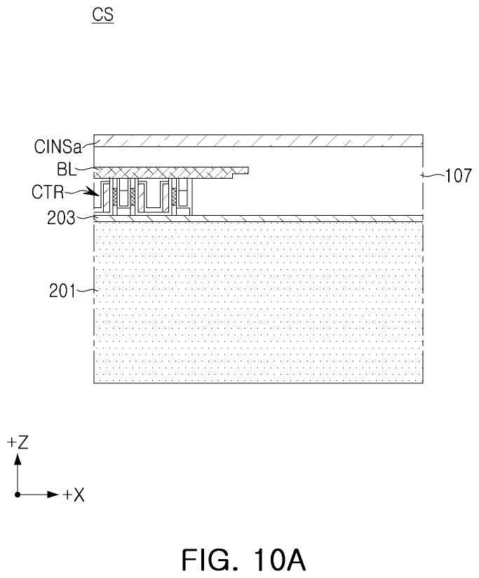

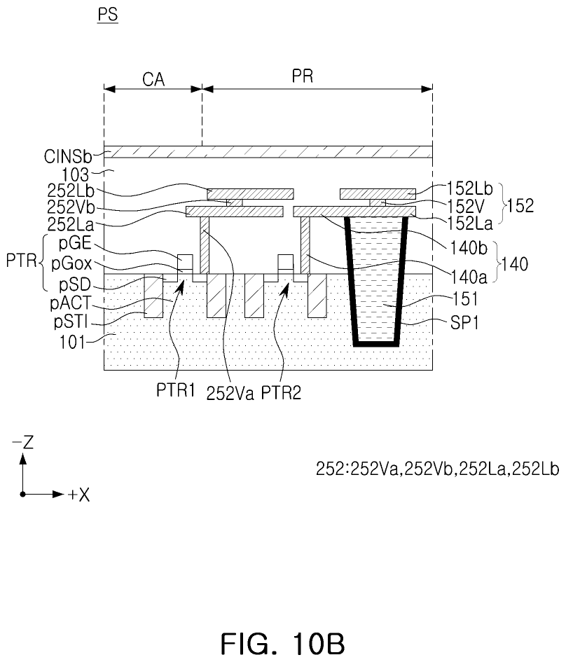

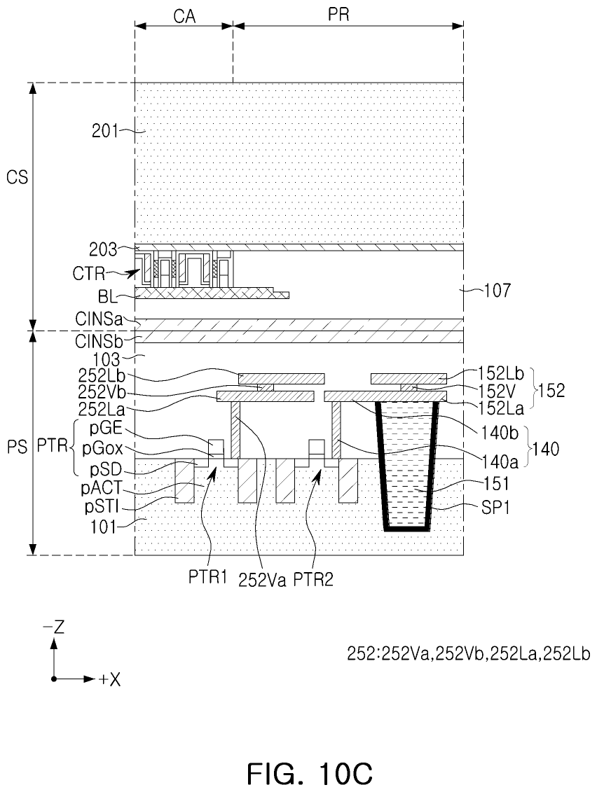

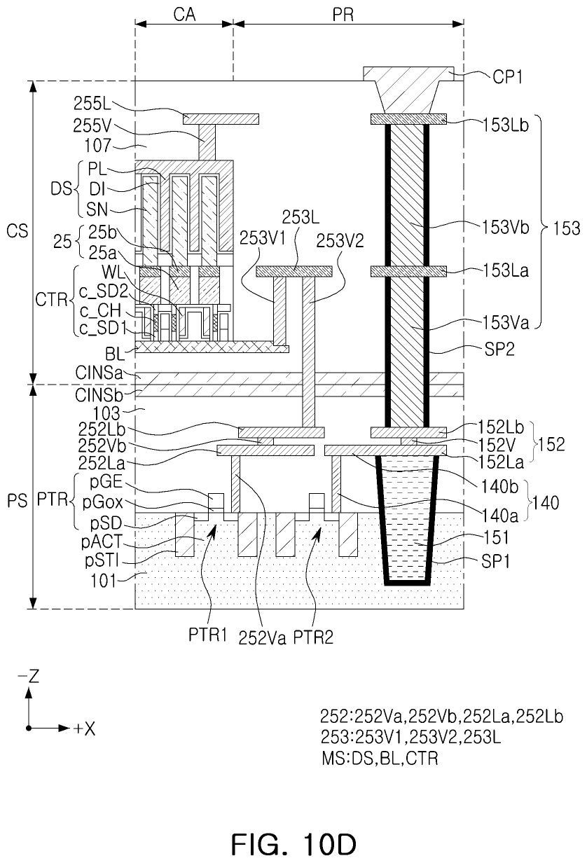

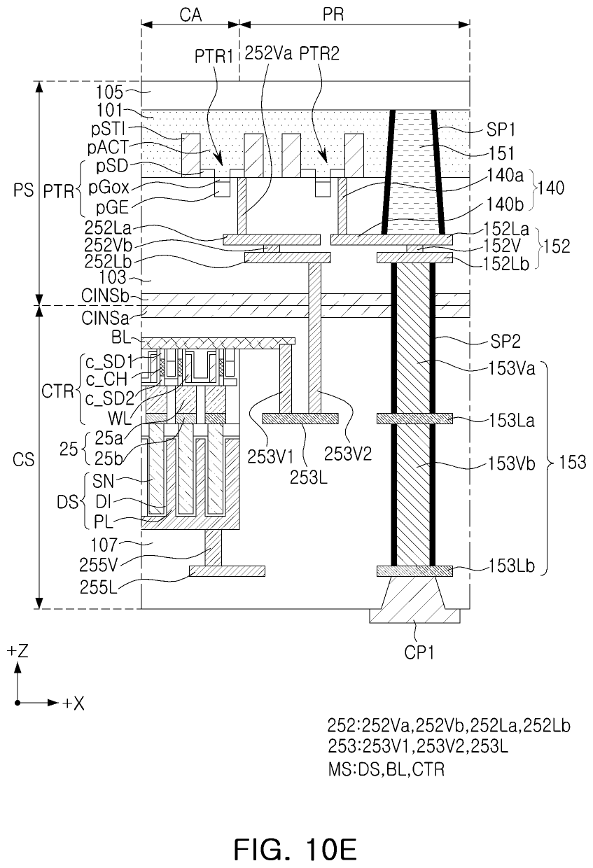

FIGS. 10A to 10E are cross-sectional views illustrating an example of a method of manufacturing the semiconductor device of FIG. 5.

Referring to FIGS. 10A to 10E, a method of manufacturing a semiconductor device may include sequentially forming a cell transistor CTR, a bit line BL, a first insulating structure 107, and a first bond insulating layer CINSa on a first base substrate (201 and 203) (see FIG. 10A), forming first and second peripheral circuits PTR1 and PTR2 and a first upper through-via 151 on one surface of a second base substrate 101, sequentially forming first and second peripheral routing interconnection structures 252 and 140, a second insulating lower structure 103, and a second bond insulating layer CINSb on the second base substrate 101 (see FIG. 10B), bonding the first bond insulating layer CINSa and the second bond insulating layer CINSb (see FIG. 10C), etching the first base substrate (201 and 203), forming an information storage structure DS, a connecting interconnection 153, and a first connection pad CP1 (see FIG. 10D), and forming a second insulating upper structure 105 and a second connection pad CP2 on the other surface of the second base substrate 101 facing the one surface of the second base substrate 101 (see FIG. 10E).

Referring to FIG. 10A, a method of manufacturing a first chip structure CS of a semiconductor device according to some embodiments may include forming a cell transistor CTR and a bit line BL on a first base substrate (201 and 203), forming a first insulating structure 107 covering or overlapping the cell transistor CTR and the bit line BL, and forming a first bond insulating layer CINSa on the first insulating structure 107. In an example, the first base substrate (201 and 203) may include a silicon on insulator (SOI) substrate. The first base substrate (201 and 203) may include a silicon layer 201 and an insulating layer 203 disposed on the silicon layer 201. In an example, the cell transistor CTR, the bit line BL, the first insulating structure 107, and the first bond insulating layer CINSa may be formed sequentially in the third direction (e.g., +Z direction).

Referring to FIG. 10B, a method of manufacturing a second chip structure PS of a semiconductor device according to some embodiments may include forming first and second peripheral circuits PTR1 and PTR2 in a direction, opposite to the third direction (+Z direction) of a second base substrate 101, forming a second insulating lower structure 103 covering or overlapping the first and second peripheral circuits PTR1 and PTR2, and forming a first upper through-via 151 and first and second peripheral routing interconnection structures 252 and 140. In an example, forming a first upper through-via 151 may include forming a conductive pillar penetrating or extending into a portion of the second base substrate 101 and forming a barrier layer at least partially surrounding lower and side surfaces of the conductive pillar. In an example, the method of manufacturing a second chip structure PS of a semiconductor device may further include forming a first insulating spacer SP1 at least partially surrounding a side surface of the first upper through-via 151.

Referring to FIG. 10C, a method of manufacturing a semiconductor device may include bonding the first bond insulating layer CINSa of the first chip structure CS of FIG. 10A and a second bond insulating layer CINSb of the second chip structure PS to face each other.

Referring to FIG. 10D, in a state in which the first chip structure CS is formed on the second chip structure PS (in a direction opposite to the third direction (e.g., −Z direction)), after etching the first base substrate (201 and 203) of FIG. 10C, an information storage structure DS, a connecting interconnection 153, and a first connection pad CP1 may be formed. In an example, the method of manufacturing a semiconductor device may further include forming a sub-routing interconnection structure (255V and 255L) and a cell routing interconnection structures 253. In an example, the forming the cell routing interconnection structure 253 may include forming a first cell routing plug 253V1 connected to the bit line BL, and forming a second cell routing plug 253V2 penetrating or extending into the first and second bond insulating layers CINSa and CINSb, and a cell horizontal interconnection 253L connecting the first and second cell routing plugs 253V1 and 253V2.

Referring to FIG. 10E, a method of manufacturing a semiconductor device may include inverting the first chip structure CS and the second chip structure PS in the third direction (+Z direction) such that the second chip structure PS is disposed on the first chip structure CS, etching the second base substrate 101 to expose an upper surface of the first upper through-via 151, and forming the second insulating upper structure 105 and a second connection pad (e.g., the second connection pad CP2 in FIG. 5) on the etched second base substrate 101.

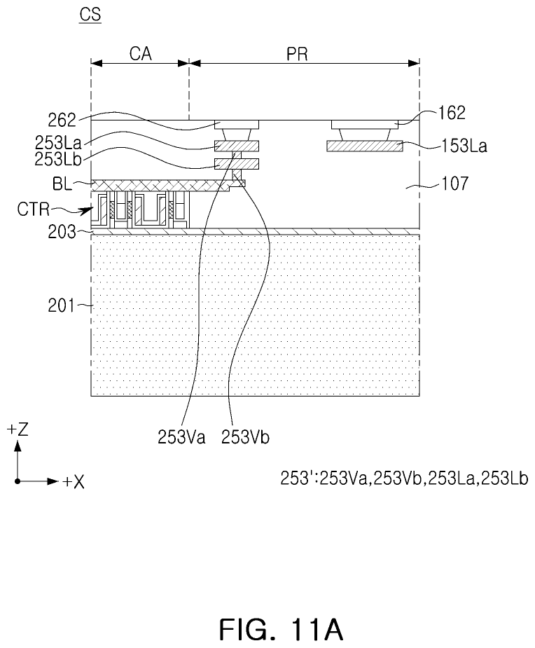

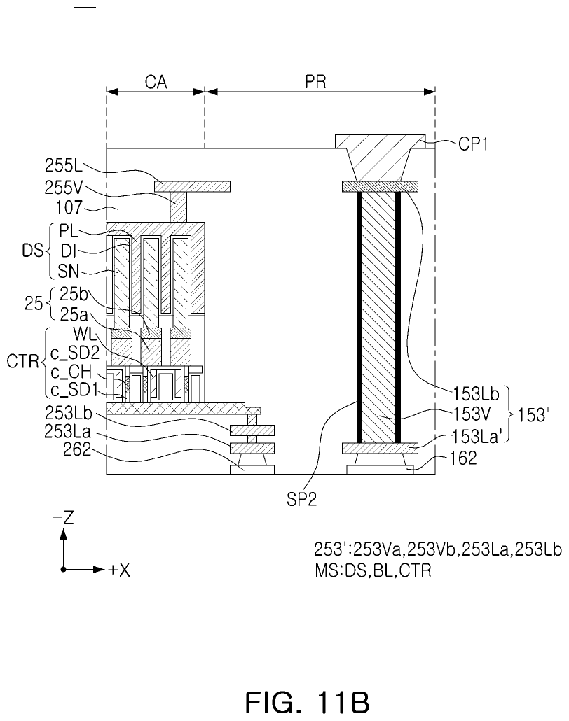

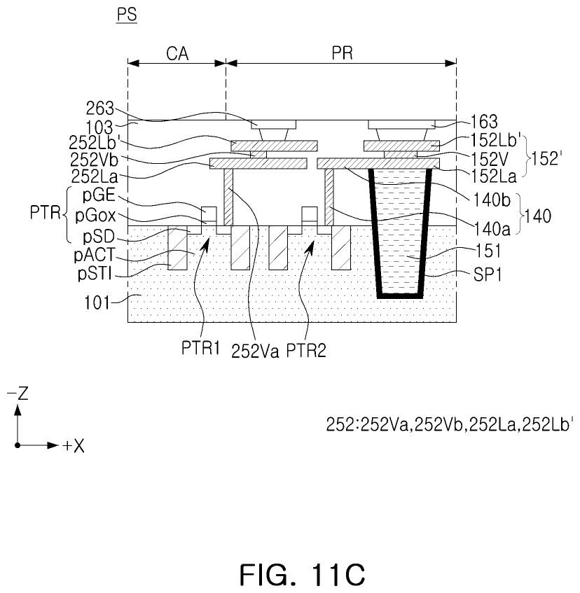

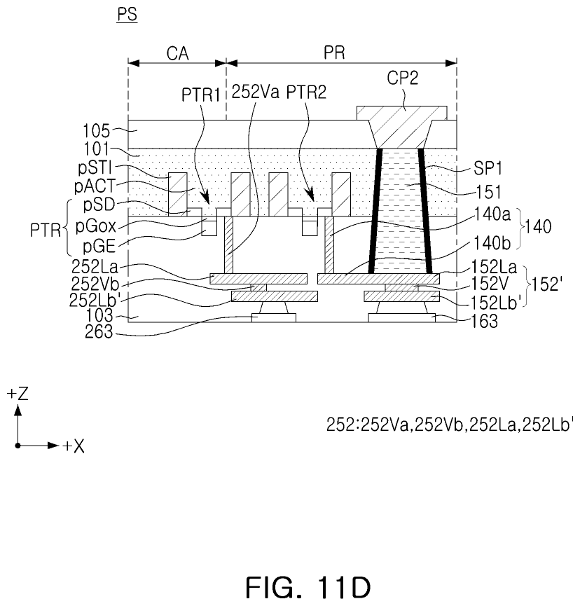

FIGS. 11A to 11D are cross-sectional views illustrating an example of a method of manufacturing the semiconductor device of FIG. 6A.

Referring to FIG. 11A, a method of manufacturing a semiconductor device may include forming a first chip structure CS. Forming a first chip structure CS may include forming a cell transistor CTR, a bit line BL, and a first insulating structure 107 on a first base substrate (201 and 203), forming a cell routing interconnection structure 253′ connected to the bit line BL and a first interconnection 153La′ of a connecting interconnection (e.g., the connecting interconnection 153′ in FIG. 6A), and forming a first sub-bonding pad 262 connected to the cell routing interconnection structure 253′, and a first bonding pad 162 connected to the first interconnection 153La′.

Referring to FIG. 11B, forming a first chip structure CS may include inverting the first chip structure CS in a direction opposite to the third direction (−Z direction), etching the first base substrate (201 and 203), forming a cell contact structure 25 and an information storage structure DS on the cell transistor CTR, forming a contact plug 153V and a second interconnection 153Lb of the connecting interconnection (e.g., the connecting interconnection 153′ in FIG. 6A), and forming a first connection pad CP1 to be connected to the second interconnection 153Lb.

Referring to FIG. 11C, the method of manufacturing a semiconductor device may include forming a second chip structure PS. Forming a second chip structure PS may include forming first and second peripheral circuits PTR1 and PTR2 in a direction opposite to the third direction (−Z direction) of a second base substrate 101, forming a second insulating lower structure 103 covering or overlapping the first and second peripheral circuits PTR1 and PTR2, forming a first upper through-via 151, forming a bridge structure 152 on the first upper through-via 151, forming first and second peripheral routing interconnection structures 252′ and 140, and forming a second bonding pad 163 and a second sub-bonding pad 263. In an example, the second bonding pad 163 may be formed to be electrically connected to a second horizontal portion 152Lb′ of the bridge structure 152. The second sub-bonding pad 263 may be formed to be electrically connected to a second horizontal portion 252Lb′ of the first peripheral routing interconnection structure 252′.

Referring to FIG. 11D, in the method of manufacturing a semiconductor device, forming a second chip structure PS may include inverting the second chip structure PS to face the third direction (+Z direction), etching the second base substrate 101 to expose an upper surface of the first upper through-via 151, and forming a second insulating upper structure 105 and a second connection pad (e.g., the second connection pad CP2 in FIG. 6A) on the second base substrate 101. In some embodiments, the method of manufacturing a semiconductor device may include forming the second connection pad CP2 of the second chip structure PS, and then bonding a first bonding pad 162 and a first sub-bonding pad 262 of the first chip structure CS and a second bonding pad 163 and a second sub-bonding pad 263 of the second chip structure PS, respectively.

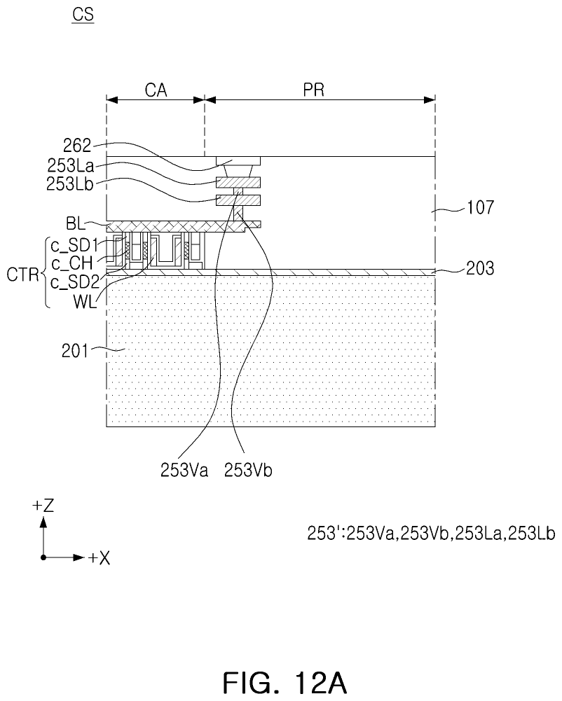

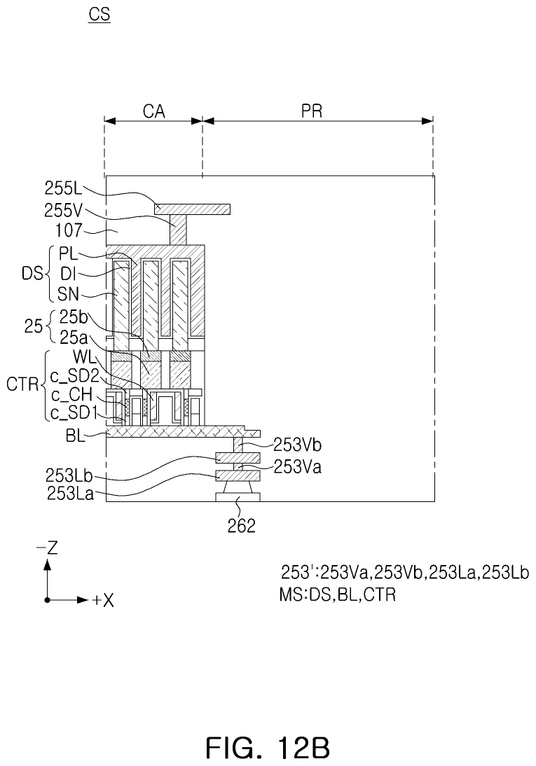

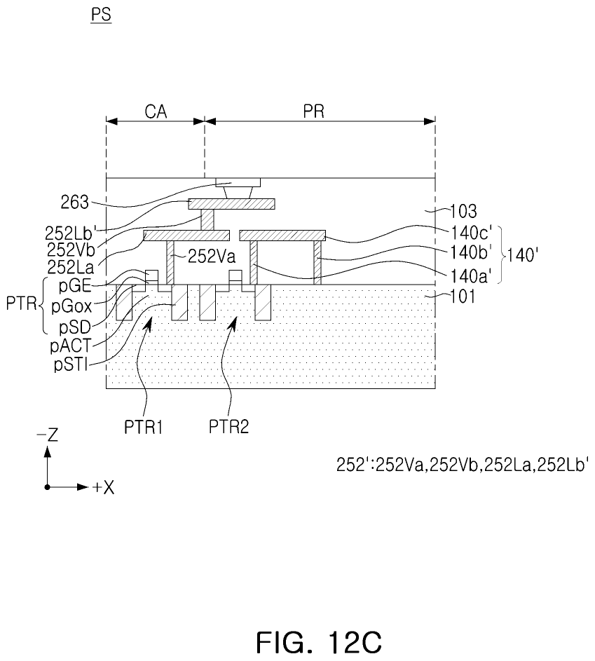

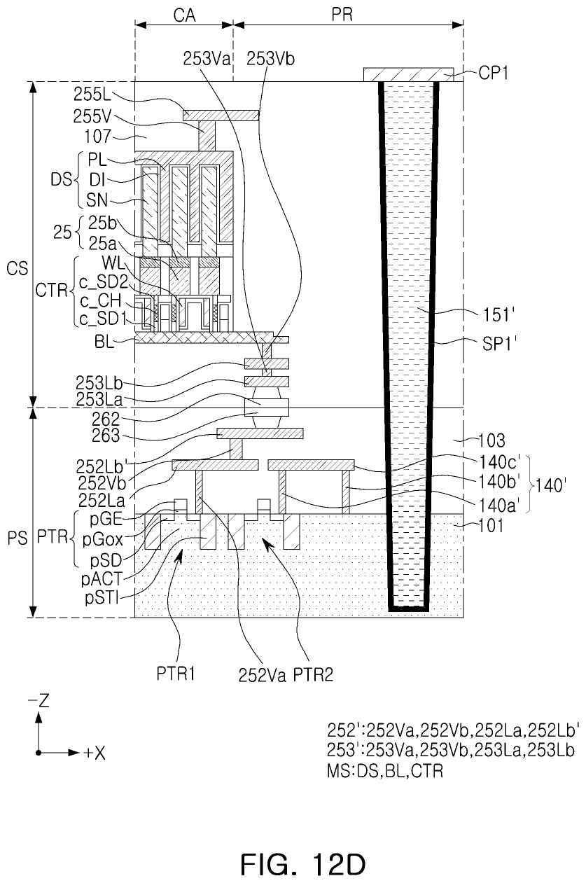

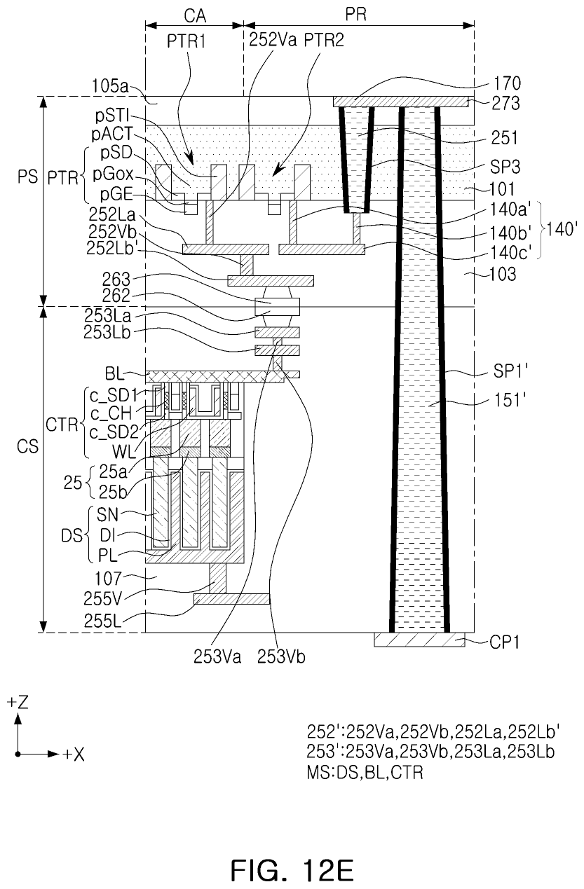

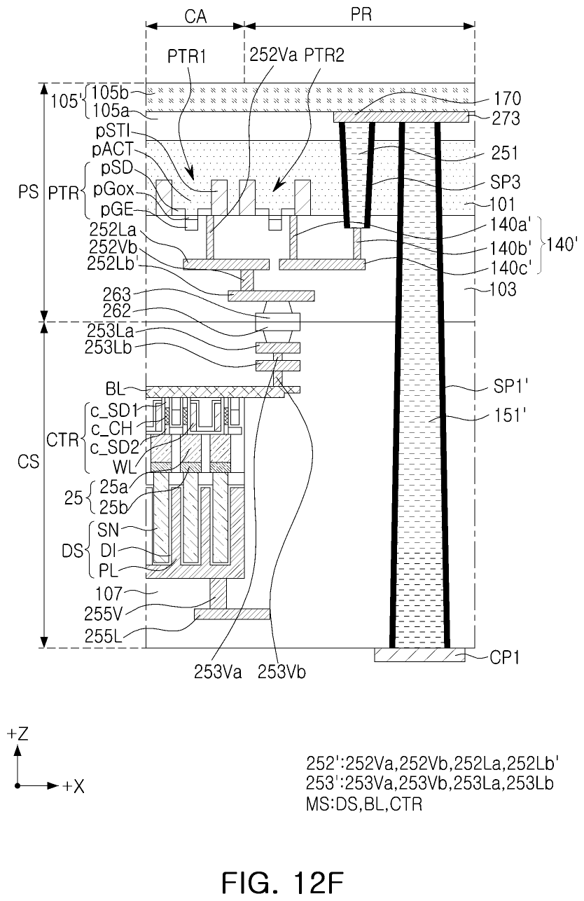

FIGS. 12A to 12F are cross-sectional views illustrating an example of a method of manufacturing the semiconductor device of FIG. 7.

Referring to FIG. 12A, a method of manufacturing a semiconductor device may include forming a first chip structure CS. Forming a first chip structure CS may include forming a cell transistor CTR, a bit line BL, and a first insulating structure 107 on a first base substrate (201 and 203), forming a cell routing interconnection structure 253′ connected to the bit line BL, and forming a first sub-bonding pad 262 connected to the cell routing interconnection structure 253′.

Referring to FIG. 12B, forming a first chip structure CS may include inverting the first chip structure CS in a direction opposite to the third direction (−Z direction), etching the first base substrate (201 and 203), and forming a cell contact structure 25 and an information storage structure DS forming a memory structure MS on the cell transistor CTR. In an example, the forming a first chip structure CS may further include forming a sub-routing interconnection structures (255V and 255L) electrically connected to the information storage structure DS.

Referring to FIG. 12C, the method of manufacturing a semiconductor device may include forming a second chip structure PS. Forming a second chip structure PS may include forming first and second peripheral circuits PTR1 and PTR2 in a direction opposite to the third direction (−Z direction) of a second base substrate 101, forming a second insulating lower structure 103 covering or overlapping the first and second peripheral circuits PTR1 and PTR2, forming a first upper through-via 151, forming a bridge structure 152 on the first upper through-via 151, forming a first peripheral routing interconnection structure 252′ electrically connected to the first peripheral circuit PTR1, and a second peripheral routing interconnection structure 140 electrically connected to the second peripheral circuit PTR2, and forming a second sub-bonding pad 263 connected to a second horizontal portion 252Lb′ of the first peripheral routing interconnection structure 252′.

Referring to FIG. 12D, the method of manufacturing a semiconductor device may include bonding the first chip structure CS to the second chip structure PS, forming a first upper through-via 151′ penetrating or extending into the first chip structure CS and a portion of the second chip structure PS, and forming a first connection pad CP1 connected to the first upper through-via 151′.

In some embodiments, bonding the first chip structure CS to the second chip structure PS (in a direction opposite to the third direction (e.g., −Z direction)) may include bonding the first sub-bonding pad 262 of the first chip structure CS to the second sub-bonding pad 263 of the second chip structure PS.

In some embodiments, a first upper through-via 151′ penetrating or extending into the first insulating structure 107 of the first chip structure CS, the second insulating lower structure 103 of the second chip structure PS, and a portion of the second base substrate 101 may be formed. Forming the first upper through-via 151′ may include forming a conductive pillar, and forming a barrier layer surrounding lower and side surfaces of the conductive pillar.

In some embodiments, forming the first connection pad CP1 may include forming the first connection pad CP1 on one side of the first upper through-via 151′ adjacent to the first chip structure CS.

Referring to FIG. 12E, the method of manufacturing a semiconductor device may include inverting the first chip structure CS in the third direction (+Z direction) such that the second chip structure PS is disposed on the first chip structure CS, etching the second base substrate 101 to expose an upper surface of the first upper through-via 151′, forming a 2-1 insulating upper structure 105a on the second base substrate 101, forming a second through-via 251 penetrating or extending into the second base substrate 101 between the first upper through-via 151′ and the second peripheral circuit PTR2, and forming a bridge pad 273 contacting the first upper through-via 151′ and the second through-via 251. In an example, the bridge pad 273 may be embedded in the 2-1 insulating upper structure 105a. An upper surface of the bridge pad 273 may be exposed externally through the 2-1 insulating upper structure 105a.

Referring to FIG. 12F, a 2-2 insulating upper structure 105b may be formed on the 2-1 insulating upper structure 105a. In an example, after the 2-2 insulating upper structure 105b is formed, a second connection pad (e.g., the second connection pad CP2 in FIG. 7) may be formed to be electrically connected to the bridge pad 273.

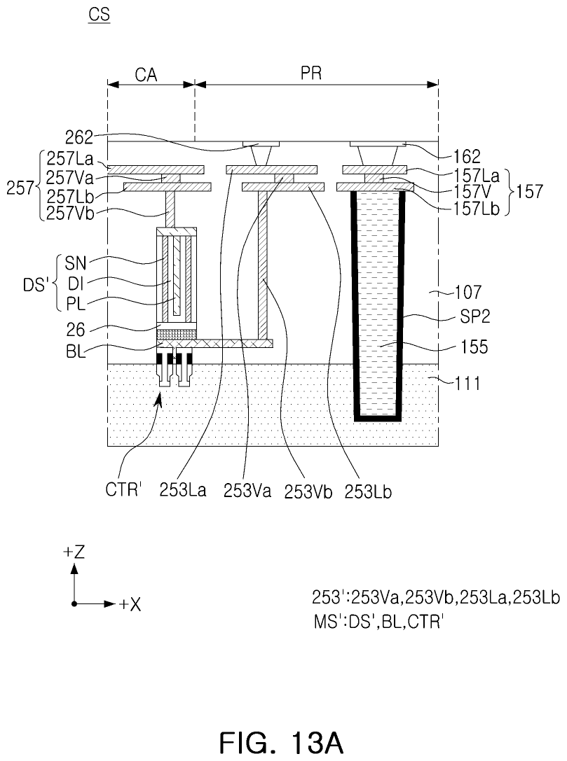

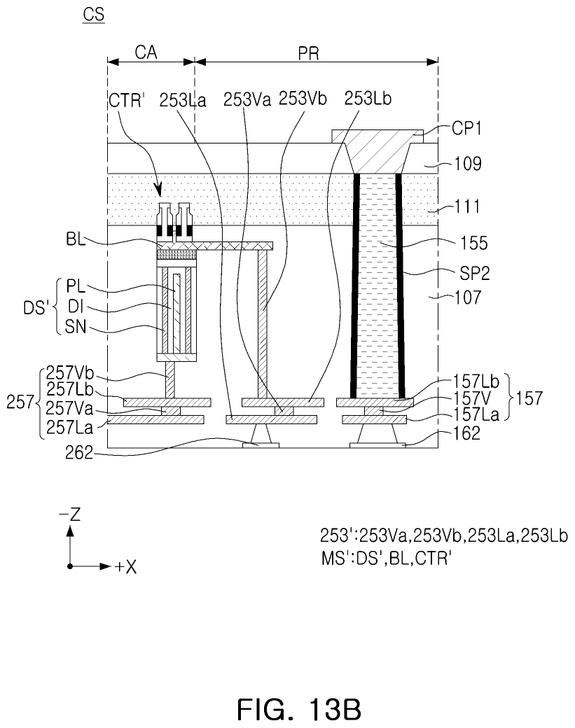

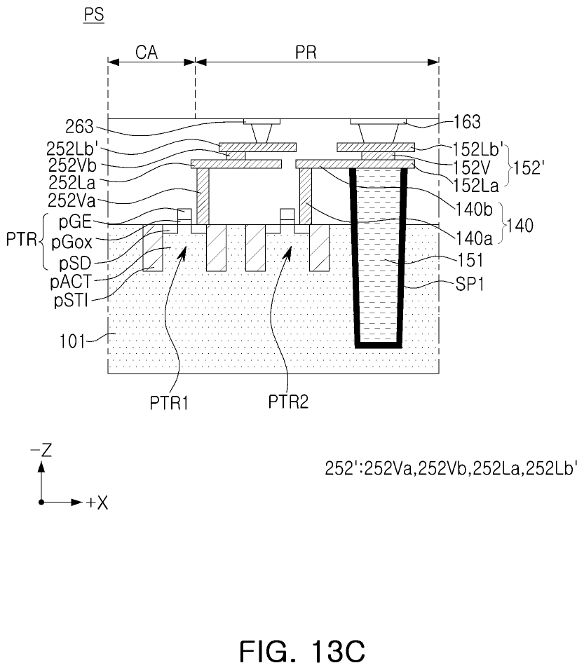

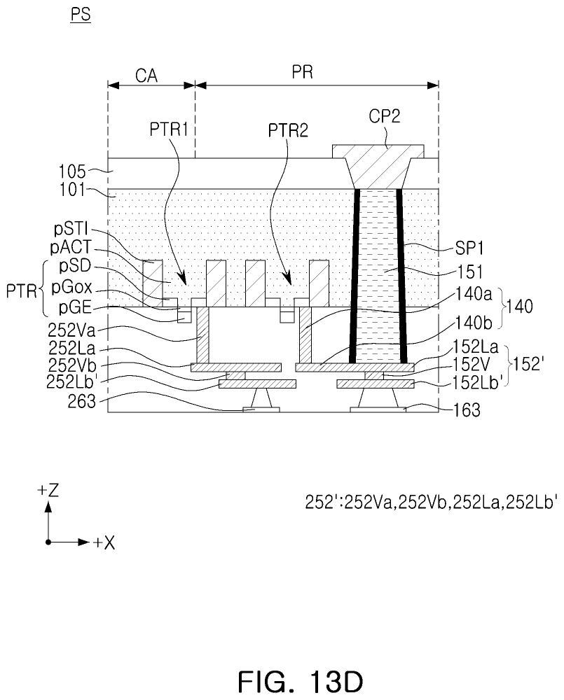

FIGS. 13A to 13D are cross-sectional views illustrating an example of a method of manufacturing the semiconductor device of FIG. 8A.

Referring to FIG. 13A, a method of manufacturing a semiconductor device may include forming a first chip structure CS. The forming a first chip structure CS may include forming a third base substrate 111, forming a cell transistor CTR′, a bit line BL, an information storage structure DS′, and a first insulating upper structure 107 on the third base substrate 111 (e.g., in the third direction (+Z direction)), forming a cell routing interconnection structure 253′ connected to the bit line BL, and a sub-routing interconnection structure 257 connected to the information storage structure DS′, forming a first lower through-via 155, forming an auxiliary interconnection structure 157 on the first lower through-via 155, forming a first sub-bonding pad 262 connected to the cell routing interconnection structure 253′, and forming a first bonding pad 162 on the auxiliary interconnection structure 157. In an example, the cell transistor CTR′, the bit line BL, and the information storage structure DS' may form a memory structure MS′.

In some embodiments, forming the first lower through-via 155 may include forming a conductive pillar penetrating or extending into a portion of the first insulating upper structure 107 and a portion of the third base substrate 111, and forming a barrier layer at least partially surrounding lower and side surfaces of the conductive pillar.

Referring to FIG. 13B, the method of manufacturing a semiconductor device may include inverting the first chip structure CS in a direction opposite to the third direction (−Z direction), etching the third base substrate 111 to expose an upper surface of the first lower through-via 155, forming a first insulating lower structure 109 on the third base substrate 111 (−Z direction), and forming a first connection pad CP1 electrically connected to the first lower through-via 155.

Referring to FIG. 13C, the method of manufacturing a semiconductor device may include forming a second chip structure PS. Forming a second chip structure PS may include forming first and second peripheral circuits PTR1 and PTR2 in a direction opposite to the third direction (−Z direction) of a second base substrate 101, forming a second insulating lower structure 103 covering or overlapping the first and second peripheral circuits PTR1 and PTR2, forming a first upper through-via 151 and first and second peripheral routing interconnection structures 252′ and 140, and forming a second bonding pad 163 and a second sub-bonding pad 263.

Referring to FIG. 13D, forming a second chip structure PS may include inverting the second chip structure PS to face the third direction (+Z direction), etching the second base substrate 101 to expose an upper surface of a conductive pillar of the first upper through-via 151, and forming a second insulating upper structure 105 and a second connection pad (e.g., the second connection pad CP2 in FIG. 8A) on the second base substrate 101. In some embodiments, the method of manufacturing a semiconductor device may include forming the second connection pad CP2 of the second chip structure PS, and then bonding a first bonding pad 162 and a first sub-bonding pad 262 of the first chip structure CS and a second bonding pad 163 and a second sub-bonding pad 263 of the second chip structure PS, respectively.

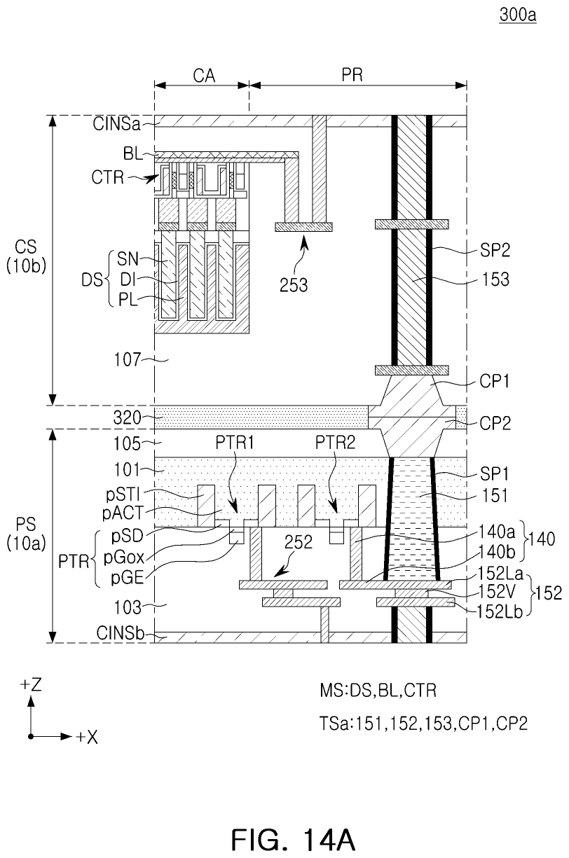

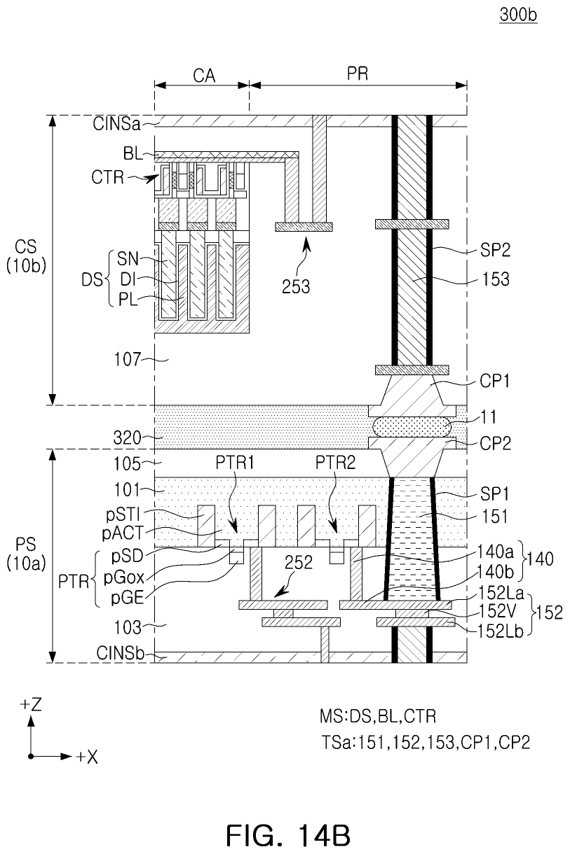

Referring to FIGS. 14A and 14B, a bonding relationship between a plurality of semiconductor chips (e.g., the plurality of semiconductor chips 10 of FIG. 3) included in a semiconductor device (e.g., the semiconductor device 300 of FIG. 1) will be described.

FIG. 14A is an enlarged view illustrating an example of a bonding relationship between the plurality of semiconductor chips of FIG. 3.

Referring to FIG. 14A, a semiconductor device 300a may include a plurality of semiconductor chips 10a and 10b and an adhesive material layer 320. In an example, the plurality of semiconductor chips 10a and 10b may include a first semiconductor chip 10a and a second semiconductor chip 10b disposed on the first semiconductor chip 10a. A second connection pad CP2 of the first semiconductor chip 10a may be in direct contact with a first connection pad CP1 of the second semiconductor chip 10b. In an example, the second connection pad CP2 of the first semiconductor chip 10a and the first connection pad CP1 of the second semiconductor chip 10b may be at least partially surrounded by the adhesive material layer 320 of the semiconductor device 300a.

FIG. 14B is an enlarged view illustrating another example of a bonding relationship between the plurality of semiconductor chips of FIG. 3.

Referring to FIG. 14B, the semiconductor device 300b may include a plurality of semiconductor chips 10a and 10b, a bump 11 disposed between the plurality of semiconductor chips 10a and 10b, and an adhesive material layer 320. In an example, the bump 11 may be disposed between a second connection pad CP2 of the first semiconductor chip 10a and a first connection pad CP1 of the second semiconductor chip 10b. The first semiconductor chip 10a may be electrically connected to the second semiconductor chip 10b through the second connection pad CP2 of the first semiconductor chip 10a, the bump 11, and the first connection pad CP1 of the second semiconductor chip 10b.

A semiconductor device according to embodiments and a semiconductor package including the same may include a connection structure penetrating or extending into a first chip structure including a memory structure and a second chip structure disposed on the first chip structure and including peripheral circuits, and the connection structure may be electrically connected to adjacent semiconductor chips by including connection pads overlapping each other. Therefore, a miniaturized semiconductor device and a semiconductor package including the same may be provided.

Effects of the present disclosure are not limited to the effects described above, and may be expanded in various manners without departing from the spirit and scope of the present disclosure.

While example embodiments have been illustrated and described above, it will be apparent to those skilled in the art that modifications and variations could be made without departing from the scope of the present disclosure as defined by the appended claims.

What is claimed is:

1. A semiconductor device comprising:
a first chip structure that comprises a memory structure and a cell routing interconnection structure that is electrically connected to the memory structure;
a second chip structure that is on the first chip structure and comprises a first peripheral circuit, a second peripheral circuit, a first peripheral routing interconnection structure that is electrically connected to the first peripheral circuit and the cell routing interconnection structure, and a second peripheral routing interconnection structure that is electrically connected to the second peripheral circuit; and
a connection structure that extends into the first chip structure and the second chip structure,
wherein the connection structure comprises:
a first connection pad;
a second connection pad overlaps the first connection pad in a first direction that is perpendicular to a lower surface of the first chip structure; and
an intermediate connection structure that is between the first connection pad and the second connection pad and is electrically connected to the second peripheral routing interconnection structure.

2. The semiconductor device of claim 1, wherein:
the first chip structure further comprises a first bond insulating layer on the memory structure and the cell routing interconnection structure,
the second chip structure further comprises a second bond insulating layer on the first bond insulating layer and disposed below the first and second peripheral circuits and the first and second routing interconnection structures, and
the intermediate connection structure comprises:
a connecting interconnection that is electrically connected to the first connection pad and extends into the first bond insulating layer and the second bond insulating layer;
a first upper through-via that is electrically connected to the second connection pad; and
a bridge structure between the connecting interconnection and the first upper through-via.

3. The semiconductor device of claim 2, wherein the second chip structure further comprises:
a first substrate;
a second insulating lower structure that is between the first substrate and the second bond insulating layer, overlaps the first peripheral circuit and the second peripheral circuit in the first direction, and overlaps the first peripheral routing interconnection structure and the second peripheral routing interconnection structure in the first direction; and
a second insulating upper structure that is on the first substrate and exposes an upper surface of the second connection pad,
wherein the first upper through-via extends into the second insulating lower structure and the first substrate.

4. The semiconductor device of claim 2, wherein the bridge structure further comprises:
a first horizontal portion that is electrically connected to the first upper through-via and the second peripheral routing interconnection structure;
a second horizontal portion that is electrically connected to the connecting interconnection; and
a first intermediate plug that is electrically connected to the first horizontal portion and the second horizontal portion.

5. The semiconductor device of claim 4, wherein the first peripheral routing interconnection structure further comprises:
a third intermediate interconnection that is separated from a lower surface of the second chip structure by a first distance, wherein the first horizontal portion of the bridge structure is separated from the lower surface of the first chip structure by the first distance;
a fourth intermediate interconnection that is separated from a lower surface of the second chip structure by a second distance, wherein the second horizontal portion is separated from the lower surface of the second chip structure by the second distance and is electrically connected to the cell routing interconnection structure;
a third intermediate plug that is electrically connected to the third intermediate interconnection and the fourth intermediate interconnection; and
a fourth intermediate plug that is electrically connected to the third intermediate interconnection and the first peripheral circuit.

6. The semiconductor device of claim 2, wherein the memory structure further comprises:
cell transistors;
bit lines that are electrically connected to respective first source/drain regions of the cell transistors; and
an information storage structure that is electrically connected to second source/drain regions of the cell transistors,
wherein the cell routing interconnection structure comprises:
a first cell routing plug that is electrically connected to ones of the bit lines;
a second cell routing plug that is electrically connected to the first peripheral routing interconnection structure; and
a cell horizontal interconnection that is electrically connected to the first cell routing plug and the second cell routing plug, and
wherein the first cell routing plug and the second cell routing plug do not overlap in the first direction.

7. The semiconductor device of claim 1, wherein the intermediate connection structure further comprises:
a connecting interconnection that is electrically connected to the first connection pad;
a first upper through-via that is electrically connected to the second connection pad;
a bridge structure that is electrically connected to the second peripheral routing interconnection structure and between the connecting interconnection and the first upper through-via;
at least one first bonding pad that is electrically connected to the connecting interconnection; and
at least one second bonding pad that is respectively on the at least one first bonding pad and is electrically connected to the connecting interconnection.

8. The semiconductor device of claim 7, wherein:
the first chip structure further comprises a first sub-bonding pad that is electrically connected to the cell routing interconnection structure, and
the second chip structure further comprises a second sub-bonding pad that is electrically connected to the first peripheral routing interconnection structure and is on the first sub-bonding pad.

9. The semiconductor device of claim 8, wherein a width of one of the at least one first bonding pad in a second direction that intersects the first direction is equal to a width of the first sub-bonding pad in the second direction.

10. The semiconductor device of claim 7, wherein:
each of the at least one first bonding pad and the at least one second bonding pad comprises a pair of bonding pads that are spaced apart from each other in a second direction that intersects the first direction.

11. The semiconductor device of claim 1, wherein the second chip structure further comprises a first substrate, a second insulating lower structure, and a second insulating upper structure, wherein:
the first substrate and is on the second insulating lower structure, wherein the second insulating lower structure overlaps the first peripheral circuit in the first direction, the second peripheral circuit in the first direction, the first peripheral routing interconnection structure in the first direction, and the second peripheral routing interconnection structure in the first direction; and
the second insulating upper structure is on the first substrate and the second insulating lower structure,
the second insulating upper structure exposes an upper surface of the second connection pad, and
the intermediate connection structure comprises:
a first upper through-via that extends into the first substrate and the first chip structure; and
an intermediate interconnection that is between the second connection pad and the first upper through-via and is electrically connected to the second peripheral routing interconnection structure.

12. The semiconductor device of claim 11, wherein the second peripheral routing interconnection structure further comprises:
a horizontal pad that is separated from a lower surface of the second chip structure by a first distance, wherein the intermediate interconnection is separated from the lower surface of the second chip structure by the first distance;
a second through-via that is spaced apart from the first upper through-via in a second direction that intersects the first direction, extends into the first substrate, and is electrically connected to the horizontal pad; and
an interconnection structure that is electrically connected to the second peripheral circuit and the second through-via.

13. The semiconductor device of claim 1, wherein the first chip structure further comprises:
a second substrate;
a first insulating lower structure that is below the second substrate; and
a first insulating upper structure that is on the memory structure and the second substrate,
wherein the first insulating lower structure exposes a lower surface of the first connection pad,
wherein the intermediate connection structure comprises:
a first lower through-via that extends into the second substrate and is electrically connected to the first connection pad;
a first upper through-via that is electrically connected to the second connection pad;
a bridge structure that is between the first lower through-via and the first upper through-via;
at least one first bonding pad that is electrically connected to the first lower through-via; and
at least one second bonding pad that is electrically connected to the second peripheral routing interconnection structure and is respectively on the at least one first bonding pad.

14. The semiconductor device of claim 13, wherein:
the first upper through-via comprises a first conductive pillar and a first barrier layer that at least partially surround side surfaces and upper surfaces of the first conductive pillar, and
the first lower through-via comprises a second conductive pillar and a second barrier layer that at least partially surround side surfaces and lower surfaces of the second conductive pillar.

15. The semiconductor device of claim 14, wherein the intermediate connection structure further comprises an auxiliary interconnection structure between the first bonding pad and the first lower through-via.

16. A semiconductor package comprising:
a lower substrate; and
a plurality of semiconductor chips that are on the lower substrate and extend in a first direction that is perpendicular to an upper surface of the lower substrate,
wherein a first semiconductor chip, among the plurality of semiconductor chips, comprises:
a first chip structure that comprises a memory structure and a cell routing interconnection structure that is electrically connected to the memory structure;
a second chip structure that is on the first chip structure and comprises a first peripheral circuit, a second peripheral circuit, a first peripheral routing interconnection structure that is electrically connected to the first peripheral circuit and the cell routing interconnection structure, and a second peripheral routing interconnection structure that is electrically connected to the second peripheral circuit; and
a connection structure that extends into the first chip structure and the second chip structure, and
wherein the connection structure comprises:
a first connection pad;
a second connection pad that overlaps the first connection pad in the first direction; and
an intermediate connection structure that is between the first connection pad and the second connection pad and is electrically connected to the second peripheral routing interconnection structure.

17. The semiconductor package of claim 16, wherein:
the plurality of semiconductor chips comprises a second semiconductor chip that is adjacent to the first semiconductor chip, and
the second connection pad of the first semiconductor chip directly contacts a first connection pad of the second semiconductor chip.

18. The semiconductor package of claim 16, wherein:
the plurality of semiconductor chips comprises a second semiconductor chip that is adjacent to the first semiconductor chip, and
the second connection pad of the first semiconductor chip further comprises a bump that is between the first semiconductor chip and a first connection pad of the second semiconductor chip.

19. A semiconductor device comprising:
a first chip structure that comprises a memory structure and a cell routing interconnection structure that is electrically connected to the memory structure;
a second chip structure that is on the first chip structure and comprises a first peripheral circuit, a second peripheral circuit, a first peripheral routing interconnection structure that is electrically connected to the first peripheral circuit and the cell routing interconnection structure, and a second peripheral routing interconnection structure that is electrically connected to the second peripheral circuit; and
a connection structure that extends into the first chip structure and the second chip structure,
wherein the second chip structure comprises:
a semiconductor substrate;
a second insulating lower structure that overlaps the first peripheral circuit in a first direction that is perpendicular to a lower surface of the first chip structure, overlaps the second peripheral circuit in the first direction, overlaps the first peripheral routing interconnection structure in the first direction, and overlaps the second peripheral routing interconnection structure in the first direction, wherein the semiconductor substrate is on the second insulating lower structure; and
a second insulating upper structure on the semiconductor substrate,
wherein the connection structure comprises:
a first connection pad;
a second connection pad that overlaps the first connection pad in the first direction; and
an intermediate connection structure that is between the first connection pad and the second connection pad and is electrically connected to the second peripheral routing interconnection structure,
wherein the intermediate connection structure comprises:
a first upper through-via that is electrically connected to the second connection pad and extends into the semiconductor substrate;
a connecting interconnection that is electrically connected to the first connection pad; and
a bridge structure that is electrically connected to the second peripheral routing interconnection structure and is between the first upper through-via and the connecting interconnection.

20. The semiconductor device of claim 19, wherein:
the first chip structure further comprises a first bond insulating layer that is on the memory structure and the cell routing interconnection structure, and
the second chip structure further comprises a second bond insulating layer that is on a lower surface of the second insulating lower structure and the first bond insulating layer,
wherein the connecting interconnection extends into the first bond insulating layer and the second bond insulating layer.
